(19) United States
(12) Patent Application Publication
(10) Pub. No.: US 2023/0189552 A1
(43) Pub. Date: Jun. 15, 2023

(54) DISPLAY PANEL AND DISPLAY APPARATUS

(71) Applicant: Samsung Display Co., LTD., Yongin-si (KR)

(72) Inventors: Jin Ho HYUN, Gwacheon-si (KR); Woo Yong SUNG, Seoul (KR)

(21) Appl. No.: 18/071,150

(22) Filed: Nov. 29, 2022

(30) Foreign Application Priority Data
Dec. 10, 2021 (KR) 10-2021-0176172

(51) Int. Cl. H01L 29/205; G06F 3/041; G06F 3/044; G09G 3/3233

(52) U.S. Cl. CPC H01L 51/5253; G06F 3/0412; G06F 3/0446; G06F 3/04164; H01L 27/3246; G09G 3/3233; G09G 2300/0842; H01L 27/323

(57) ABSTRACT

A display panel includes a first dam structure disposed in a first surrounding area in contact with one side of a display area in a non-display area, a second dam structure disposed in a second surrounding area in contact with another side of the display area in the non-display area and having a same thickness as the first dam structure, and a sealing structure covering an emitting array. A second sealing layer of the sealing structure includes a first side portion corresponding to the first dam structure and having a cross section with a first curvature and a second side portion corresponding to the second dam structure and having a cross section with a second curvature greater than the first curvature.

This application claims priority to Korean Patent Application No. 10-2021-0176172, filed on Dec. 10, 2021, and all the benefits accruing therefrom under 35 U.S.C. §119, the content of which in its entirety is herein incorporated by reference.

### BACKGROUND

### 1. Field

The disclosure relates to a display panel and a display apparatus.

### 2. Description of the Related Art

As the information society develops, the demand for display apparatuses for displaying images has increased and diversified. For example, display apparatuses have been applied to various electronic devices such as smartphones, digital cameras, laptop computers, navigation devices, and smart televisions.

The display apparatus includes a display panel that emits light for image display.

At least one surface of the display panel may include a display area that emits light for image display and a non-display area disposed around the display area.

In the display apparatus, as a width of the non-display area of one surface of the display panel is decreased, a width of the display area may be relatively increased. In this case, a display quality such as resolution, an aspect ratio, and aesthetics may be improved.

### SUMMARY

Embodiments of the disclosure provide a display panel and a display apparatus in which a width of a non-display area may be decreased.

According to an embodiment, a display panel includes a support substrate including a display area including a plurality of pixel areas which emits light for image display and a non-display area disposed around the display area, an emitting array disposed on the support substrate and including a plurality of emitting devices corresponding to the plurality of pixel areas, a first dam structure disposed in a first surrounding area in contact with one side of the display area in the non-display area, a second dam structure disposed in a second surrounding area in contact with the other side of the display area in the non-display area and having a same thickness as the first dam structure, and a sealing structure covering the emitting array. In such an embodiment, the sealing structure includes a first sealing layer disposed on the emitting array and including an inorganic insulating material, a second sealing layer disposed on the first sealing layer and including an organic insulating material, and a third sealing layer disposed on the first sealing layer, covering the second sealing layer, and including the inorganic insulating material. In such an embodiment, the third sealing layer is in contact with an edge of the first sealing layer. In such an embodiment, the second sealing layer includes a first side portion corresponding to the first dam structure and having a cross section with a first curvature and a second side portion corresponding to the second dam structure and having a cross section with a second curvature greater than the first curvature.

In an embodiment, a plurality of grooves may be defined in an upper surface of the second dam structure through at least portions of the second dam structure to extend in parallel with each other.

In an embodiment, a gradient of a side surface of the second dam structure defining the plurality of grooves with respect to the upper surface or a lower surface of the second dam structure may be in a range of about 45° to about 90°.

In an embodiment, the first side portion may cover the first dam structure. In such an embodiment, a height of the first side portion with respect to the support substrate may gradually decrease as the first side portion becomes closer to an edge of the support substrate corresponding to the first surrounding area.

In an embodiment, a gradient of a side surface of the first dam structure may be less than about 45°.

In an embodiment, a height of the first side portion with respect to the support substrate may gradually decrease with a first slope corresponding to the first curvature as the first side portion becomes more distant from the display area. In such an embodiment, a height of the second side portion with respect to the support substrate may decrease with a second slope corresponding to the second curvature greater than the first curvature and greater than the first slope as the second side portion becomes more distant from the display area. In such an embodiment, a width of the second side portion may be smaller than a width of the first side portion.

In an embodiment, the display area may have a rectangular shape including first and second sides opposing each other and third and fourth sides in contact with the first and second sides and opposing each other. In such an embodiment, the first surrounding area may be in contact with the first side of the display area. In such an embodiment, the second surrounding area may be in contact with the second side, the third side, and the fourth side of the display area.

In an embodiment, the display panel may further include a circuit array disposed on the support substrate and including a plurality of pixel driving circuits corresponding to the plurality of pixel areas and connected to the plurality of emitting devices, and a via layer covering the circuit array. In such an embodiment, the emitting array may include a plurality of first electrodes disposed on the via layer and corresponding to the plurality of pixel areas, a pixel defining layer disposed on the via layer, between the plurality of pixel areas, and covering edges of each of the plurality of first electrodes, a plurality of emitting layers disposed on the plurality of first electrodes, respectively, and a second electrode disposed on the pixel defining layer and the plurality of emitting layers and corresponding to the plurality of pixel areas. In such an embodiment, each of the first dam structure and the second dam structure may include a first dam layer defined by a same layer as the via layer, and a second dam layer disposed on the first dam layer and defined by a same layer as the pixel defining layer.

In an embodiment, the plurality of grooves may be defined through at least portions of the second dam layer of the second dam structure.

In an embodiment, the emitting array may further include a spacer disposed on the pixel defining layer between the plurality of pixel areas. In such an embodiment, each of the first dam structure and the second dam structure may further include a third dam layer disposed on the second dam layer and defined by a same layer as the spacer. In such an embodiment, The plurality of grooves may extend through at least portions of the third dam layer of the second dam structure.

According to an embodiment, a display apparatus comprising a display panel which emits light for image display, and a touch sensing unit disposed on the display panel. In such an embodiment, the display panel includes a support substrate including a display area including a plurality of pixel areas for the image display and a non-display area disposed around the display area, an emitting array disposed on the support substrate and including a plurality of emitting devices corresponding to the plurality of pixel areas, a first dam structure disposed in a first surrounding area in contact with one side of the display area in the non-display area, a second dam structure disposed in a second surrounding area in contact with the other side of the display area in the non-display area, where a plurality of grooves is defined in an upper surface of the second dam structure through at least portions of the second dam structure to extend in parallel with each other, and a sealing structure covering the emitting array. In such an embodiment, , a gradient of a side surface of the second dam structure defining the plurality of grooves with respect to the upper surface or a lower surface of the second dam structure is in a range of about 45° to about 90°.

In an embodiment, the sealing structure may include a first sealing layer disposed on the emitting array and including an inorganic insulating material, a second sealing layer disposed on the first sealing layer and including an organic insulating material, and a third sealing layer disposed on the first sealing layer, covering the second sealing layer, and including the inorganic insulating material. In such an embodiment, the third sealing layer may be in contact with an edge of the first sealing layer. In such an embodiment, the second sealing layer may be surrounded by the first dam structure and the second dam structure.

In an embodiment, the second sealing layer may include a first side portion corresponding to the first dam structure and having a cross section with a first curvature and a second side portion corresponding to the second dam structure and having a cross section with a second curvature greater than the first curvature.

In an embodiment, a height of the first side portion with respect to the support substrate may gradually decrease with a first slope corresponding to the first curvature as the first side portion becomes more distant from the display area. In such an embodiment, a height of the second side portion with respect to the support substrate may decrease with a second slope corresponding to the second curvature and greater than the first slope as the second side portion becomes more distant from the display area. In such an embodiment, a width of the second side portion may be smaller than a width of the first side portion.

In an embodiment, the display area may have a rectangular shape including first and second sides opposing each other and third and fourth sides in contact with the first and second sides and opposing each other. In such an embodiment, the first surrounding area may be in contact with the first side of the display area. In such an embodiment, the second surrounding area may be in contact with the second side, the third side, and the fourth side of the display area.

In an embodiment, the display panel may further include a circuit array disposed on the support substrate and including a plurality of pixel driving circuits corresponding to the plurality of pixel areas and connected to the plurality of emitting devices, a via layer covering the circuit array, and a plurality of signal pads disposed in a pad area adjacent to an edge of the support substrate in the first surrounding area, where a driving circuit is connected to the plurality of signal pads. In such an embodiment, the emitting array may include a plurality of first electrodes disposed on the via layer and corresponding to the plurality of pixel areas, a pixel defining layer disposed on the via layer, between the plurality of pixel areas, and covering edges of each of the plurality of first electrodes, a plurality of emitting layers disposed on the plurality of first electrodes, respectively, and a second electrode disposed on the pixel defining layer and the plurality of emitting layers and corresponding to the plurality of pixel areas.

In an embodiment, each of the first dam structure and the second dam structure may include a first dam layer defined by a same layer as the via layer, and a second dam layer disposed on the first dam layer and defined by a same layer as the pixel defining layer. In such an embodiment, the plurality of grooves may be defined through at least portions of the second dam layer of the second dam structure.

In an embodiment, the emitting array may further include a spacer disposed on the pixel defining layer between the plurality of pixel areas. In such an embodiment, the second electrode may cover the spacer. In such an embodiment, each of the first dam structure and the second dam structure includes a first dam layer defined by a same layer as the via layer, a second dam layer disposed on the first dam layer and defined by a same layer as the pixel defining layer, and a third dam layer disposed on the second dam layer and defined by a same layer as the spacer. In such an embodiment, The plurality of grooves may be defined through at least portions of the third dam layer of the second dam structure.

In an embodiment, the plurality of signal pads may include a plurality of first touch pads and a plurality of second touch pads. In such an embodiment, the touch sensing unit may be disposed on the sealing structure. In such an embodiment, The touch sensing unit includes a receiving line connected between one receiving electrode adjacent to one side of an edge of a touch sensing area corresponding to the display area among a plurality of receiving electrodes arranged in parallel in a first direction in the touch sensing area and the second touch pad, a first touch driving line connected between one touch driving electrode adj acent to another side of the edge of the touch sensing area among a plurality of touch driving electrodes arranged in parallel in a second direction crossing the first direction in the touch sensing area and one of the plurality of first touch pads, and a second touch driving line connected between one touch driving electrode adjacent to another side of the edge of the touch sensing area among the plurality of touch driving electrodes arranged in parallel in the second direction crossing the first direction in the touch sensing area and another of the plurality of first touch pads.

In an embodiment, a gradient of a side surface of the first dam structure may be less than about 45°.

In embodiments of the invention, a display panel includes a first dam structure disposed in a first surrounding area in contact with one side of a display area in a non-display area, a second dam structure disposed in a second surrounding area in contact with another side of the display area in the non-display area, and a sealing structure having a structure in which a first sealing layer covering the emitting array and including an inorganic insulating material, a second sealing layer including an organic insulating material, and a third sealing layer including an inorganic insulating material are sequentially stacked. In such embodiments, the second sealing layer includes a first side portion corresponding to the first dam structure and having a cross section with a first curvature and a second side portion corresponding to the second dam structure and having a cross section with a second curvature greater than the first curvature.

In such embodiments,, the side portions of the second sealing layer do not have cross sections of a same curvature as each other, or a second side portion of the second sealing layer in a second surrounding area excluding the first surrounding area in which signal pads are disposed has a cross section with a curvature greater than that in a first side portion of the second sealing layer in the first surrounding area. Accordingly, the second side portion of the second sealing layer may have a width smaller than that of the first side portion due to the curvature greater than that of the first side portion. Therefore, width of the non-display area may be reduced by decreasing the width of the second side portion of the second sealing layer, such that a display quality of the display panel and a display apparatus including the display panel may be improved.

### BRIEF DESCRIPTION OF THE DRAWINGS

The above and other features of the disclosure will become more apparent by describing in detail embodiments thereof with reference to the attached drawings, in which:

FIG. 1 is a perspective view illustrating a display apparatus according to an embodiment;

FIGS. 2 and 3 are plan views illustrating the display apparatus of FIG. 1;

FIG. 4 is a cross-sectional view illustrating an embodiment taken along line A-A′ of FIG. 3;

FIG. 5A is a plan view illustrating an embodiment of a display area and a non-display area of FIG. 4;

FIG. 5B is an enlarged view of the encircled portion of FIG. 5A;

FIG. 6 is a plan view illustrating an embodiment of a circuit array of FIG. 4;

FIG. 7 is an equivalent circuit diagram illustrating an embodiment of a pixel driving circuit corresponding to any one main pixel area of FIG. 6;

FIG. 8 is a plan view illustrating an embodiment of a touch sensing unit of FIG. 4;

FIG. 9 is an enlarged plan view illustrating an embodiment of portion D of FIG. 8 in detail;

FIG. 10 is an enlarged plan view illustrating an embodiment of portion E of FIG. 9 in detail;

FIG. 11 is a cross-sectional view illustrating an embodiment taken along line F-F′ of FIG. 10;

FIG. 12 is a cross-sectional view illustrating an embodiment of a first dam structure corresponding to line B-B′ of FIG. 6;

FIG. 13 is an enlarged view illustrating portion G of FIG. 12 in detail;

FIG. 14 is a cross-sectional view illustrating an embodiment of a second dam structure corresponding to line C-C′ of FIG. 6;

FIG. 15 is an enlarged view illustrating portion H of FIG. 14 in detail;

FIG. 16 is a cross-sectional view illustrating an alternative embodiment of a first dam structure corresponding to line B-B′ of FIG. 6;

FIG. 17 is a cross-sectional view illustrating an alternative embodiment of a second dam structure corresponding to line C-C′ of FIG. 6; and

FIG. 18 is a cross-sectional view illustrating another alternative embodiment of a second dam structure corresponding to line C-C′ of FIG. 6.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout..

Some of the parts which are not associated with the description may not be provided in order to describe embodiments of the disclosure.

It will also be understood that when a layer is referred to as being “on” another layer or substrate, it can be directly on the other layer or substrate, or intervening layers may also be present. In contrast, when an element is referred to as being “directly on” another element, there may be no intervening elements present.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ± 30%, 20%, 10%, 5% of the stated value.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from ” for the purpose of its meaning and interpretation. For example, “at least one of A and B” may be understood to mean “A, B, or A and B.”

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the invention will be described in detail with reference to the accompanying drawings.

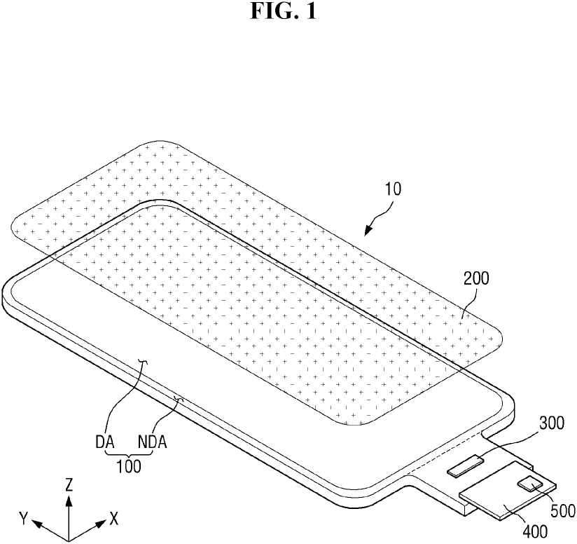

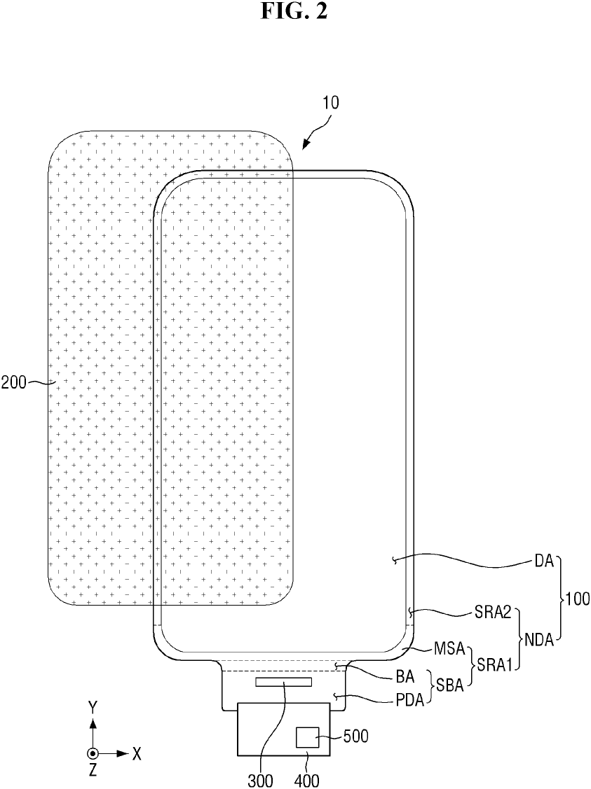

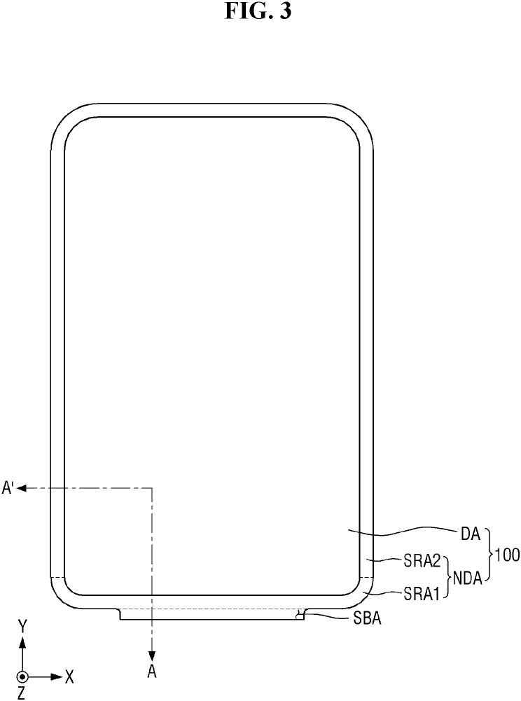

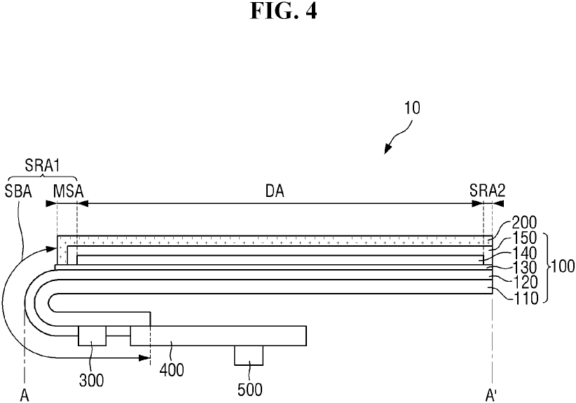

FIG. 1 is a perspective view illustrating a display apparatus according to an embodiment. FIGS. 2 and 3 are plan views illustrating the display apparatus of FIG. 1. FIG. 4 is a cross-sectional view illustrating an embodiment taken along line A-A′ of FIG. 3.

Referring to FIG. 1, a display apparatus 10 according to an embodiment may be included in portable electronic devices such as mobile phones, smartphones, tablet personal computers (PCs), mobile communication terminals, electronic notebooks, electronic books, portable multimedia players (PMPs), navigation devices, and ultra mobile PCs (UMPCs). Alternatively, the display apparatus 10 according to an embodiment may be provided as a display unit of televisions, laptop computers, monitors, billboards, or the Internet of Things (IOTs). Alternatively, the display apparatus 10 according to an embodiment may be included in wearable devices such as smart watches, watch phones, glasses-type displays, and head mounted displays (HMDs). Alternatively, the display apparatus 10 according to an embodiment may be provided as a center information display (CID) disposed on an instrument board, a center fascia, or a dashboard of a vehicle, a room mirror display substituting for a side mirror of the vehicle, or a display disposed on a rear surface of a front seat as entertainment for a rear seat of the vehicle.

The display apparatus 10 according to an embodiment may be an organic light emitting display apparatus using an organic light emitting diode. However, an embodiment is not limited to the organic light emitting display apparatus, and may be applied to any structure including an organic film for sealing. in an embodiment, for example, the display apparatus 10 may be any one of a quantum dot light emitting display apparatus including a quantum dot emitting layer, an inorganic light emitting display apparatus including an inorganic semiconductor, and a micro or nano light emitting display apparatus using micro or nano light emitting diodes (micro LEDs or nano LEDs).

The display apparatus 10 may include a display panel 100 that emits light for image display, and a touch sensing unit 200 disposed on the display panel 100.

In an embodiment, the display apparatus 10 may further include a display driving circuit 300 and a display circuit board 400 driving the display panel 100, and a touch driving circuit 500 driving the touch sensing unit 200.

Referring to FIG. 2, an embodiment of the display panel 100 may be provided in the form of a flat plate or in a flat plate-like shape. However, this is only an example, and the display panel 100 according to an embodiment may be flexible to be easily deformed, and may be in a form or have a shape in which at least one side thereof is bent, folded, or rolled.

The display panel 100 includes a display area DA that emits light for image displaying, and a non-display area NDA, which is a surrounding area of the display area DA.

In an embodiment, the display area DA may have a rectangular shape having short sides in a first direction (X-axis direction) and long sides in a second direction (Y-axis direction) perpendicular to the first direction (X-axis direction). A corner of the display area DA may be a right-angled contact point or a curved contact point having a predetermined curvature. According to an embodiment, a shape of the display area DA is not limited to the rectangular shape, and may be variously modified to a polygonal shape, a circular shape, and an elliptical shape depending on a device to which the display apparatus 10 is applied.

The non-display area NDA includes a first surrounding area SRA1 in contact with one side (e.g., a lower side of FIG. 2) of the display area DA and a second surrounding area SRA2 in contact with another side (e.g., any one of the left side, the right side, and the upper side of FIG. 2) of the display area DA.

In an embodiment, for example, where the display area DA has a rectangular shape including first and second sides opposing each other and third and fourth sides opposing each other, the first surrounding area SRA1 may be in contact with the first side of the display area DA, and the second surrounding area SRA2 may be in contact with the second side, the third side, and the fourth side of the display area DA.

The first surrounding area SRA1 includes a pad area PDA which is adjacent to an edge of a support substrate 110 (see FIG. 4) and in which signal pads (not illustrated) to which the display circuit board 400 is connected are disposed.

Referring to FIGS. 3 and 4, in an embodiment where the display panel 100 is flexible, a portion of the first surrounding area SRA1 is bent toward a rear surface of the display panel 100, such that the pad area PDA to which the display circuit board 400 is connected in the first surrounding area SRA1 may be disposed on the rear surface of the display panel 100.

In such an embodiment, as illustrated in FIG. 2, the first surrounding area SRA1 may include a main surrounding area MSA in contact with one side of the display area DA and a sub-surrounding area SBA protruding from the main surrounding area MSA and disposed below the display panel 100 in a bending form.

The sub-surrounding area SBA may include a bending area BA in contact with the main surrounding area MSA and deformed or bent into a bending form and the pad area PAD which extends from the bending area BA and to which the display circuit board 400 is connected.

In an embodiment, as illustrated in FIG. 4, the bending area BA of the sub-surrounding area SBA is bent toward the rear surface of the display panel 100, such that the support substrate 110 is defined or bent into a form in which a portion of the pad area PDA and a portion of the display area DA at least partially face each other.

The touch sensing unit 200 may be disposed on the display panel 100.

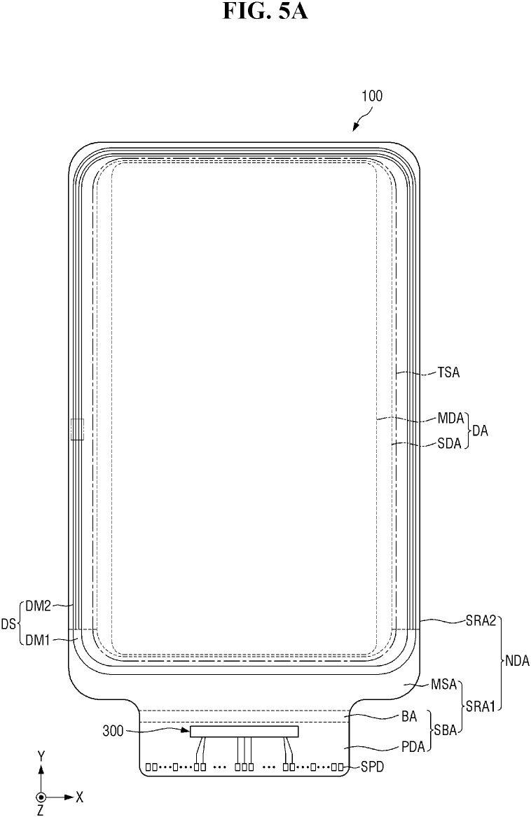

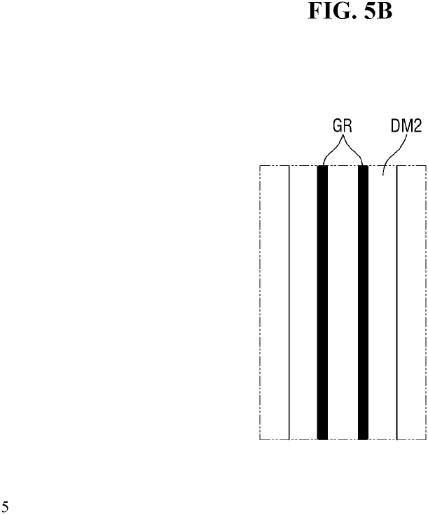

The touch sensing unit 200 generates a sensing signal for detecting a point at which a user’s touch input is performed in at least a touch sensing area TSA (see FIG. 5A) corresponding to the display area DA. The touch sensing unit 200 will be described in detail later.

The display driving circuit 300 supplies signals and voltages for driving the display panel 100.

In an embodiment, for example, the display driving circuit 300 may supply data signals to data lines of the display panel 100. In an embodiment, the display driving circuit 300 may supply first driving power to first driving power lines of the display panel 100. In an embodiment, the display driving circuit 300 may supply a scan control signal to a scan driver embedded in the display panel 100.

The display driving circuit 300 may be provided as an integrated circuit chip. The integrated circuit chip of the display driving circuit 300 may be mounted in the pad area PDA of the first surrounding area SRA1 of the display panel 100.

The integrated circuit chip of the display driving circuit 300 may be mounted directly on the display panel 100 in a chip on glass (COG) manner, a chip on plastic (COP) manner, or an ultrasonic bonding manner.

Alternatively, the integrated circuit chip of the display driving circuit 300 may be mounted on the display circuit board 400.

The display circuit board 400 may include an anisotropic conductive film. In an embodiment, for example, the display circuit board 400 may be a flexible printed circuit board, a printed circuit board, or a flexible film such as a chip on film.

The display circuit board 400 may be attached to the signal pads of the display panel 100. Therefore, lead lines (not illustrated) of the display circuit board 400 may be electrically connected to the signal pads of the display panel 100.

The touch driving circuit 500 may be provided as or defined by an integrated circuit chip, and the integrated circuit chip of the touch driving circuit 500 may be mounted on the display circuit board 400.

The touch driving circuit 500 may be connected to the touch sensing unit 200 through the signal pads of the display panel 100 and the display circuit board 400.

Referring to FIG. 4, the display panel 100 may include a support substrate 110, a circuit array 120 on the support substrate 110, a via layer 130 on the circuit array 120, an emitting array 140 on the via layer 130, and a sealing structure 150 on the emitting array 140.

The support substrate 110 may be provided in the form of a flexible flat plate that may be easily deformed, for example, bent, folded, or rolled.

In an embodiment, the support substrate 110 may include or be made of an insulating material such as glass, quartz, or a polymer resin. In such an embodiment, the polymer resin may include polyethersulphone (PES), polyacrylate (PA), polyarylate (PAR), polyetherimide (PEI), polyethylene naphthalate (PEN), polyethylene terepthalate (PET), polyphenylene sulfide (PPS), polyallylate, polyimide (PI), polycarbonate (PC), cellulose triacetate (TAC), cellulose acetate propionate (CAP), or combinations thereof.

The circuit array 120 is disposed on the support substrate 110.

The circuit array 120 may include a plurality of pixel driving circuits corresponding to a plurality of pixel areas arranged in the display area DA.

The via layer 130 flatly covers the circuit array 120. The via layer 130 may have a structure in which at least one organic insulating film is stacked.

In an embodiment, for example, the organic insulating film constituting the via layer 130 may include or be made of at least one selected from an acrylic resin, an epoxy resin, a phenolic resin, a polyamide resin, and a polyimide resin.

The emitting array 140 is disposed on the display area DA of the via layer 130.

The emitting array 140 includes a plurality of emitting devices corresponding to the plurality of pixel areas.

The sealing structure 150 is disposed on the non-display area NDA of the via layer 130 and the emitting array 140, and seals the emitting array 140. The sealing structure 150 may have a structure in which at least one inorganic film and at least one organic film are alternately stacked.

The touch sensing unit 200 may be disposed on the sealing structure 150.

The touch sensing unit 200 may extend to the first surrounding area SRA1 of the non-display area NDA in order to be connected to the signal pads (not illustrated) disposed in the sub-surrounding area SBA of the first surrounding area SRA1 of the non-display area NDA.

FIG. 5A is a plan view illustrating an embodiment of a display area and a non-display area of FIG. 4, and FIG. 5B is an enlarged view of the encircled portion of FIG. 5A.

Referring to FIG. 5A, an embodiment of the display panel 100 includes a display area DA that emits light for image display, and a non-display area NDA, which is a surrounding area of the display area DA.

The display area DA may include a main display area MDA corresponding to a first resolution and sub-display areas SDA disposed on opposing sides of the main display area MDA in the first direction (X-axis direction) and corresponding to a second resolution smaller than the first resolution.

The touch sensing area TSA of the touch sensing unit 200 for sensing the user’s touch input may correspond to at least the display area DA, such that a user may be allowed to recognize an area for a touch input.

The touch sensing area TSA may extend to a portion of the non-display area NDA including the sub-display area SDA within a range in which capacitance greater than or equal to a threshold for generating a sensing signal is secured. In an embodiment, for example, in order to secure the capacitance greater than or equal to the threshold for generating the sensing signal, the touch sensing area TSA may be limited within an area surrounded by a dam structure DS.

The non-display area NDA may include a first surrounding area SRA1 including a pad area PDA and in contact with one side of the display area DA and a second surrounding area SRA2 in contact with the other side of the display area DA.

The first surrounding area SRA1 may be in contact with one side (lower side of FIG. 5) of the display area DA in the second direction (Y-axis direction).

The first surrounding area SRA1 may include a main surrounding area MSA in contact with one side of the display area DA and a sub-surrounding area SBA protruding from the main surrounding area MSA.

The sub-surrounding area SBA may include a bending area BA deformed in a bending shape and the pad area PDA disposed on a rear surface of the display panel 100 by the bending area BA. In the pad area PDA, signal pads SPD to which the display circuit board 400 is connected may be disposed, and the display driving circuit 300 may be mounted.

The second surrounding area SRA2 may be the remaining area of the non-display area NDA excluding the first surrounding area SRA1. In an embodiment, the second surrounding area SRA2 may be an area of the non-display area NDA in contact with both sides of the display area DA in the first direction (X-axis direction) and the other side of the display area DA of the non-display area NDA in the second direction (Y-axis direction).

In such an embodiment, the other side of the display area DA in contact with the second surrounding area SRA2 may be at least one of one side (e.g., the left side of FIG. 5) of the display area DA in the first direction (X-axis direction), the other side (.g., the right side of FIG. 5) of the display area DA in the first direction (X-axis direction), and the other side (.g., the upper side of FIG. 5) of the display area DA in the second direction (Y-axis direction).

The display panel 100 further includes a dam structure DS provided as a barrier including or made of a liquid material to dispose the organic film of the sealing structure 150. The dam structure DS includes a first dam structure DM1 disposed in the first surrounding area SRA1 and a second dam structure DM2 disposed in the second surrounding area SRA2.

Here, the first dam structure DM1 and the second dam structure DM2 are provided by a same process, and may thus have a same thickness as and similar shape to each other.

In an embodiment of the display panel 100, as shown in FIG. 5B, a plurality of grooves GR may be defined in an upper surface of the second dam structure DM2 to extend in parallel with each other.

A gradient of a side surface is higher in the plurality of grooves GR than in the first dam structure DM1 and the second dam structure DM2. The plurality of grooves GR are for increasing a contact angle when a liquid material of a second sealing layer is widely expanded while spreading.

In an embodiment, a side portion of the organic film corresponding to the first dam structure DM1 in which the plurality of grooves GR are not disposed may climb over the first dam structure DM1 to have a thickness gradually decreasing with a gentle slope, and another side portion of the organic film corresponding to the second dam structure DM2 in which the plurality of grooves GR are disposed may be blocked by the first dam structure DM1 and the plurality of grooves GR to have a thickness decreasing with a relatively steep slope.

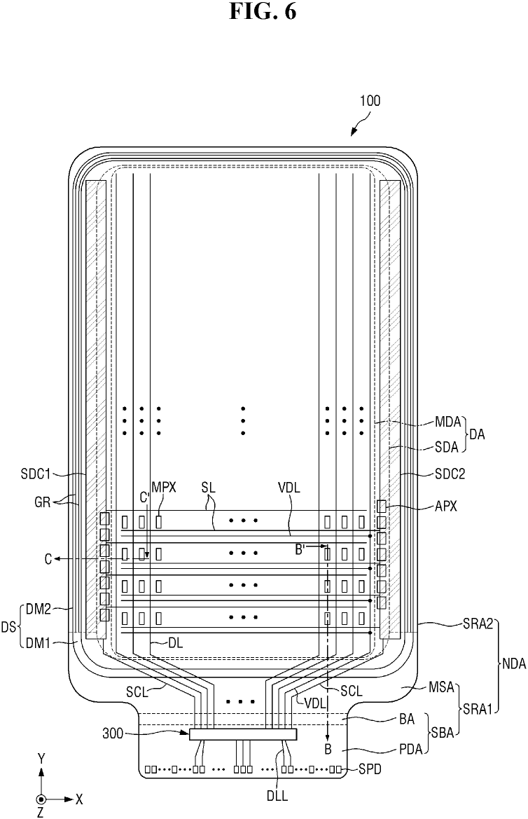

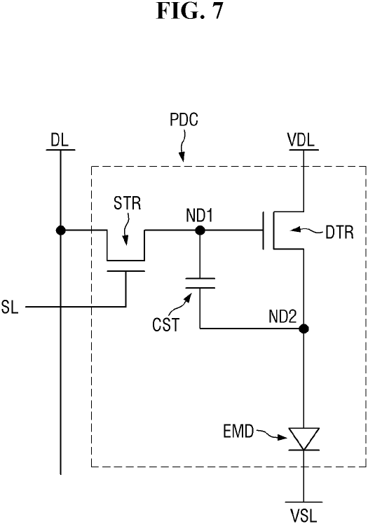

FIG. 6 is a plan view illustrating an embodiment of a circuit array of FIG. 4. FIG. 7 is an equivalent circuit diagram illustrating an embodiment of a pixel driving circuit corresponding to any one main pixel area of FIG. 6.

Referring to FIG. 6, an embodiment of the display panel 100 may further include a plurality of main pixel areas MPX arranged at a first resolution in the main display area MDA and a plurality of additional pixel areas APX arranged in the sub-display areas SDA.

The display panel 100 may further include scan lines SL disposed in the main display area MDA, extending in the first direction (X-axis direction), and for supplying scan signals, and data lines DL disposed in the main display area MDA, extending in the second direction (Y-axis direction), and for supplying data signals.

In an embodiment, the display panel 100 may further include first driving power lines VDL for supplying first driving power for driving emitting devices. The first driving power lines VDL may receive the first driving power from the display driving circuit 300 or the display circuit board 400.

In an embodiment, the display panel 100 may further include a scan driving circuit disposed in the sub-display area SDA and connected to the scan lines SL.

The scan driving circuit may include a first scan driving circuit SDC1 disposed in the sub-display area SDA in contact with one side (e.g., the left side of FIG. 6) of the main display area MDA in the first direction (X-axis direction) and the non-display area NDA and a second scan driving circuit SDC2 disposed in the sub-display area SDA in contact with the other side (e.g., the right side of FIG. 6) of the main display area MDA in the first direction (X-axis direction) and the non-display area NDA.

In an embodiment, the first scan driving circuit SDC1 and the second scan driving circuit SDC2 may be disposed over the sub-display areas SDA disposed on both sides of the main display area MDA in the first direction (X-axis direction) and the non-display area NDA.

However, that illustrated in FIG. 6 is only an example, and the scan driving circuit may be disposed in the sub-display area SDA in contact with any one of opposing sides of the main display area MDA in the first direction (X-axis direction) and the non-display area NDA.

Each of the first scan driving circuit SDC1 and the second scan driving circuit SDC2 may sequentially output the scan signals to the scan lines SL disposed in the display area DA based on scan control signals of the display driving circuit 300 supplied through scan control lines SCL.

Alternatively, the first scan driving circuit SDC1 and the second scan driving circuit SDC2 may further supply switching signals for controlling turn-on/turn-off operations of a transistor (not illustrated) included in a pixel driving circuit of each of the plurality of main pixel areas MPX and the plurality of additional pixel areas APX, in addition to the scan signals.

The plurality of additional pixel areas APX disposed in the sub-display areas SDA may overlap the first scan driving circuit SDC1 and the second scan driving circuit SDC2. In an embodiment, at least a portion of each of the first scan driving circuit SDC1 and the second scan driving circuit SDC2 is disposed in the sub-display areas SDA including the plurality of additional pixel areas APX that emit light. Therefore, an increase in a width of the non-display area NDA due to the disposition of the first scan driving circuit SDC1 and the second scan driving circuit SDC2 may be reduced.

The display panel 100 may further include data link lines DLL disposed in the pad area PDA of the first surrounding area SRA1 for linking the display driving circuit 300 and the signal pads SPD to each other.

The display driving circuit 300 may receive digital video data and timing signals supplied from the display circuit board 400 through the data link lines DLL.

The display driving circuit 300 may supply the data signals to the data lines DL of the display area DA based on the digital video data and the timing signals, and supply the scan control signal to each of the first scan driving circuit SDC1 and the second scan driving circuit SDC2.

Each of the plurality of main pixel areas MPX and the plurality of additional pixel areas APX may include an emitting device and a pixel driving circuit for supplying a driving signal to the emitting device.

The pixel driving circuits of the plurality of main pixel areas MPX may be disposed in the main display area MDA together with the emitting devices of the plurality of main pixel areas MPX. In an embodiment, due to the first scan driving circuit SDC1 and the second scan driving circuit SDC2 disposed in the sub-display areas SDA, the pixel driving circuit of each of the plurality of additional pixel areas APX may be disposed in extra areas of the sub-display areas SDA in which the first scan driving circuit SDC1 and the second scan driving circuit SDC2 are not disposed or an extra area of the main display area MDA in which the pixel driving circuits of the plurality of main pixel areas MPX are not disposed. Accordingly, each of the plurality of additional pixel areas APX may include an emitting device having a width greater than that of the plurality of main pixel areas MPX to correspond to the second resolution.

Referring to FIG. 7, an embodiment of a pixel driving circuit PDC may include an emitting device EMD, a driving transistor DTR, a switching transistor STR, and a storage capacitor CST.

The emitting device EMD may be an organic light emitting diode including a first electrode and a second electrode facing each other and an emitting layer including or made of an organic emitting material between the first electrode and the second electrode. Alternatively, the emitting device EMD may include an emitting layer including or made of an inorganic photoelectric conversion material rather than an organic emitting material.

The driving transistor DTR is connected to the emitting device EMD in series between a first driving power line VDL and a second driving power line VSL. The second driving power line VSL may supply second driving power having a lower voltage level than first driving power of the first driving power line.

In an embodiment, for example, an anode electrode of the emitting device EMD may be connected to a drain electrode of the driving transistor DTR, and a cathode electrode of the emitting device EMD may be connected to the second driving power line VSL.

In such an embodiment, a gate electrode of the driving transistor DTR may be connected to a first node ND1 corresponding to the switching transistor STR, one of a source electrode and the drain electrode of the driving transistor DTR may be connected to a second node ND2 corresponding to the emitting device EMD, and the other of the source electrode and the drain electrode of the driving transistor DTR may be connected to the first driving power line VDL.

The storage capacitor CST is disposed between a first node ND1 and a second node ND2. The first node ND1 is a contact point between the gate electrode of the driving transistor DTR and the switching transistor STR. The second node ND2 is a contact point between the driving transistor DTR and the emitting device EMD.

The switching transistor STR is disposed between a data line DL and the first node ND1, and is turned on based on a scan signal of a scan line SL. In such an embodiment, a gate electrode of the switching transistor STR may be connected to the scan line SL, one of a source electrode and a drain electrode of the switching transistor STR may be connected to the data line DL, and the other of the source electrode and the drain electrode of the switching transistor STR may be connected to the first node ND1.

Accordingly, when the scan signal is supplied to the scan line SL, the switching transistor STR is turned on based on the scan signal of the scan line SL, and a data signal of the data line DL is transferred to the first node ND1 through the tumed-on switching transistor STR.

The driving transistor DTR generates a driving current having a magnitude corresponding to a voltage difference between the first node ND1 and the first driving power line VDL, such that the emitting device EMD emits light having luminance corresponding to the driving current of the driving transistor DTR.

FIG. 7 illustrates an embodiment of the pixel driving circuit PDC having a 2T1C structure, but this is only an example. That is, the pixel driving circuit PDC of the display panel 100 according to an embodiment is not limited to that illustrated in FIG. 7, and alternatively, may be a circuit including three or more transistors or two or more capacitors.

FIG. 7 illustrates an embodiment where the driving transistor DTR and the switching transistor STR are defined by or formed as metal oxide semiconductor field effect transistors (MOSFETs), but this is only an example. In an embodiment, at least one transistor included in the pixel driving circuit PDC of the display panel 100 according to an embodiment may be a P-type MOSFET.

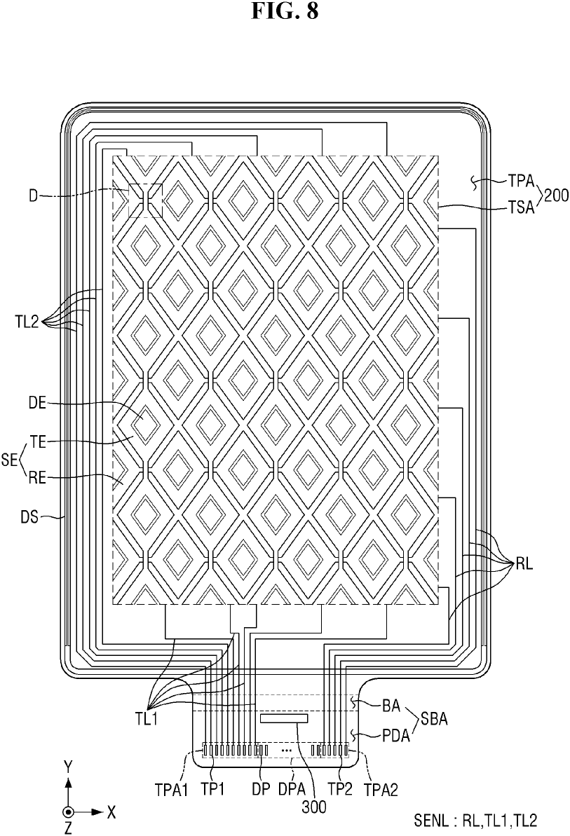

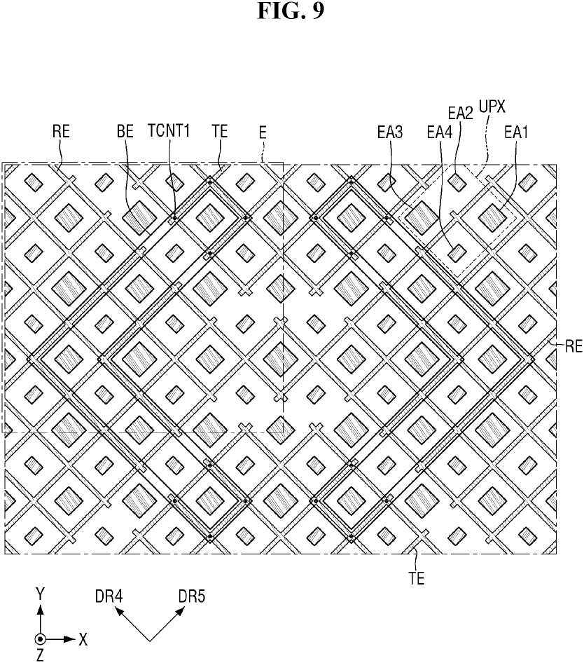

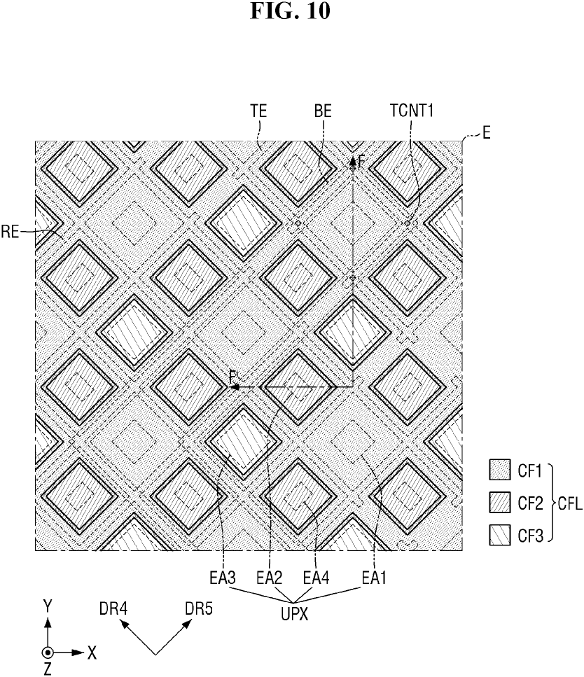

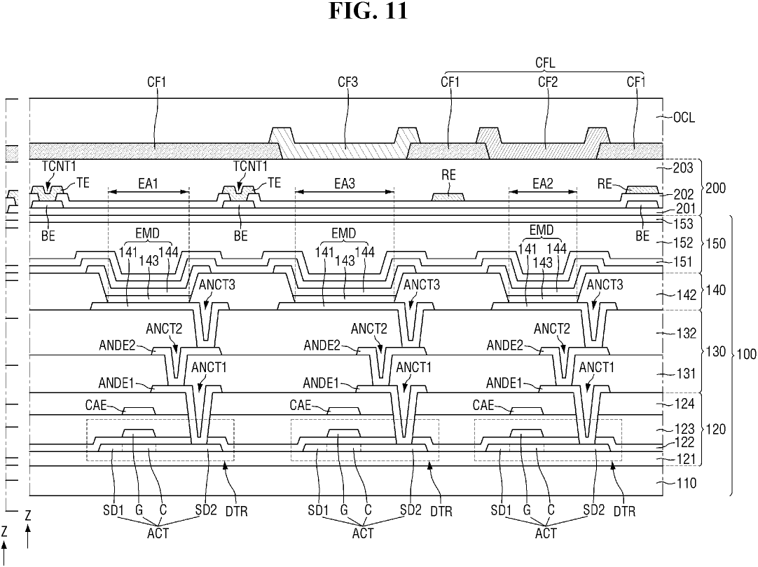

FIG. 8 is a plan view illustrating an embodiment of a touch sensing unit of FIG. 4. FIG. 9 is an enlarged plan view illustrating an embodiment of portion D of FIG. 8 in detail. FIG. 10 is an enlarged plan view illustrating an embodiment of portion E of FIG. 9 in detail. FIG. 11 is a cross-sectional view illustrating an embodiment taken along line F-F′ of FIG. 10.

FIG. 8 illustrates an embodiment where the touch sensing unit 200 is a capacitance type touch sensing unit. In such an embodiment, the touch driving circuit 500 may sense a touch based on whether or not capacitance has been changed. However, FIG. 8 is only an example, and the touch sensing unit 200 according to an embodiment is not limited to that illustrated in FIG. 4.

FIG. 8 illustrates only some of components of the touch sensing unit 200 for convenience of illustration and description.

Referring to FIG. 8, the touch sensing unit 200 includes a touch sensing area TSA for sensing a user’s touch and a touch periphery area TPA disposed around the touch sensing area TSA.

As described above with reference to FIG. 5A, the touch sensing area TSA corresponds to the display area DA. Accordingly, the touch periphery area TPA, which is a peripheral area of the touch sensing area TSA, may correspond to the non-display area NDA, which is a surrounding area of the display area DA. In an embodiment, for example, the touch sensing area TSA may overlap the display area DA and an edge of the non-display area NDA in contact with the display area DA.

The touch periphery area TPA may overlap the remaining portion of the non-display area NDA that does not correspond to the touch sensing area TSA.

The touch sensing unit 200 may include sensor electrodes SE and dummy patterns DE arranged in a matrix form in the touch sensing area TSA for generating mutual capacitance and a sensor line SENL disposed in the touch periphery area TPA.

The sensor electrode SE may include a touch driving electrode TE to which a touch driving signal is applied and a receiving electrode RE for receiving a voltage charged in mutual capacitance with the touch driving electrode TE.

The sensor line SENL may include first touch driving lines TL1 and second touch driving lines TL2 corresponding to the touch driving electrodes TE for receiving lines RL corresponding to the receiving electrodes RE.

The receiving electrodes RE may be arranged in parallel in the first direction (X-axis direction). The receiving electrodes RE neighboring to each other in the first direction (X-axis direction) may be connected to each other through protruding portions in the first direction (X-axis direction).

The touch driving electrodes TE may be arranged in parallel in the second direction (Y-axis direction). The touch driving electrodes TE neighboring to each other in the second direction (Y-axis direction) may be connected to each other through bridge electrodes BE (see FIG. 10) in the second direction (Y-axis direction).

Each of the receiving electrodes RE may be formed to surround the dummy pattern DE disposed at the center thereof.

Each of the dummy patterns DE is spaced apart from the touch driving electrode TE or the receiving electrode RE surrounding each of the dummy patterns DE. The dummy pattern DE may be maintained in a floating state.

FIG. 8 illustrates an embodiment where the touch driving electrodes TE, the receiving electrodes RE, and the dummy patterns DE each may have a rhombic shape in a plan view, but an embodiment is not limited to that illustrated in FIG. 8. In an embodiment, for example, a shape of each of the touch driving electrodes TE, the receiving electrodes RE, and the dummy patterns DE may be a quadrangular shape other than the rhombic shape, a polygonal shape other than a quadrangular shape, a circular shape, or an elliptical shape.

The signal pads SPD disposed in the pad area PDA of the display panel 100 may include display pads for transmitting and receiving signals for driving the display panel 100 and touch pads for transmitting and receiving signals for driving the touch sensing unit 200.

In an embodiment, for example, the pad area PDA may include a display pad area DPA adj acent to the display driving circuit 300 and a first touch pad area TPA1 and a second touchpad area TPA2 disposed on opposing sides of the display pad area DPA

A plurality of display pads DP transferring signals for driving the display panel 100 to the display area DA or the display driving circuit 300 may be disposed in the display pad area DPA.

A plurality of first touch pads TP1 corresponding to the touch driving electrodes TE may be disposed in the first touch pad area TPA1.

A plurality of second touch pads TP2 corresponding to the receiving electrodes RE may be disposed in the second touchpad area TPA2.

The receiving line RL corresponds to a touch horizontal group including the receiving electrodes RE arranged in parallel in the first direction (X-axis direction) and connected to each other. In an embodiment, the receiving line RL may be connected between one receiving electrode RE adjacent to an edge of the touch sensing area TSA among the receiving electrodes RE arranged in parallel in the first direction (X-axis direction) and connected to each other and the second touch pad TP2.

The first touch driving line TL1 and the second touch driving line TL2 correspond to both ends of a touch vertical group including the touch driving electrodes TE arranged in parallel in the second direction (Y-axis direction) and connected to each other. In an embodiment, for example, one side (lower side in FIG. 8) of each vertical touch group may be connected to the first touch driving line TL1, and the other side (upper side in FIG. 8) of each touch vertical group may be connected to the second touch driving line TL2.

In such an embodiment, one touch driving electrode TE in contact with a lower edge of the touch sensing area TSA among the touch driving electrodes TE arranged in parallel in the second direction (Y-axis direction) and connected to each other may be connected to one first touch pad TP1 through the first touch driving line TL1, and another touch driving electrode TE in contact with an upper edge of the touch sensing area TSA among the touch driving electrodes TE may be connected to another first touch pad TP1 through the second touch driving line TL2.

In such an embodiment, a portion of each of the first touch driving lines TL1, the second touch driving lines TL2, and the receiving lines RL may be disposed in an area between the dam structure DS including the first dam structure DM1 (see FIG. 5) and the second dam structure DM2 (see FIG. 5) and the touch sensing area TSA. In such an embodiment, a portion of each of the first touch driving lines TL1, the second touch driving lines TL2, and the receiving lines RL may be disposed in an area between the dam structure DS in the touch periphery area TPA and the touch sensing area TSA.

In an embodiment, as shown in FIG. 8, a portion of each of the second touch driving lines TL2 and the receiving lines RL may be disposed in an area between the second dam structure DM2 (see FIG. 5) and the touch sensing area TSA. In such an embodiment, a defect due to a disconnection of the first touch driving lines TL1, the second touch driving lines TL2, and the receiving lines RL due to step structures while crossing the second dam structure DM2 may be effectively prevented.

In such an embodiment, the other portion of each of the first touch driving lines TL1, the second touch driving lines TL2, and the receiving lines RL may extend to the outside of the dam structure DS to be disposed in the bending area BA and the pad area PDA.

Referring to FIG. 9, the touch driving electrode TE and the receiving electrode RE are disposed in a same layer and are spaced apart from each other. In such an embodiment, a gap is defined between the touch driving electrode TE and the receiving electrode RE adjacent to each other.

A bridge electrode BE for connecting between the touch driving electrodes TE neighboring to each other in the second direction (Y-axis direction) may be disposed in a different layer from the touch driving electrode TE and the receiving electrode RE.

FIG. 9 illustrates an embodiment where the bridge electrode BE has a bent shape in a plan view, but an embodiment is not limited to that illustrated in FIG. 9.

The touch driving electrodes TE adjacent to each other in the second direction (Y-axis direction) may be connected to each other through a plurality of bridge electrodes BE. In such an embodiment, reliability of a connection between the touch driving electrodes TE may be improved.

FIG. 9 illustrates an embodiment where two bridge electrodes BE parallel to each other are disposed between the touch driving electrodes TE neighboring to each other in the second direction (Y-axis direction), but an embodiment is not limited to that illustrated in FIG. 9.

One side of the bridge electrode BE may be connected to one of the touch driving electrodes TE adjacent to each other in the second direction (Y-axis direction) through a touch contact hole TCNT1, and the other side of the bridge electrode BE may be connected to the other of the touch driving electrodes TE adjacent to each other in the second direction (the Y-axis direction) through a touch contact hole TCNT1.

Each of the touch driving electrodes TE, the receiving electrodes RE, and the bridge electrodes BE may have a mesh shape or a shape of a mesh structure in a plan view. The dummy patterns DE may also have a mesh shape or a shape of a mesh structure in a plan view. In such an embodiment, an area in which the emitting device of each of the plurality of main pixel areas MPX and the plurality of additional pixel areas APX overlaps the touch driving electrode TE, the receiving electrode RE, the dummy pattern DE, and the bridge electrode BE may be decreased, and thus, a decrease in light emission efficiency due to the touch driving electrode TE, the receiving electrode RE, the dummy pattern DE, and the bridge electrode BE may be reduced.

Each of the plurality of main pixel areas MPX and the plurality of additional pixel areas APX may be one of a first emission area EA1 that emits light of a first color, a second emission area EA2 that emits light of a second color, a third emission area EA3 that emits light of a third color, and a fourth emission area EA4 parallel to the second emission area EA2 in the second direction (Y-axis direction) and emitting the light of the second color.

In an embodiment, a unit pixel UPX, which is a basic unit for displaying various colors, may be provided by the first emission area EA1, the second emission area EA2, the third emission area EA3, and the fourth emission area EA4 adjacent to each other.

In an embodiment, the first emission area EA1 and the second emission area EA2 may be adjacent to each other in a fourth direction DR4, and the third emission area EA3 and the fourth emission area EA4 may be adjacent to each other in the fourth direction DR4. The first emission area EA1 and the fourth emission area EA4 may be adjacent to each other in a fifth direction DR5, and the second emission area EA2 and the third emission area EA3 may be adjacent to each other in the fifth direction DR5.

The fourth direction DR4 is a diagonal direction between the first direction (X-axis direction) and the second direction (Y-axis direction). The fifth direction DR5 is a direction orthogonal to the fourth direction DR4. In an embodiment, for example, the fourth direction DR4 may be a direction inclined by about 45° with respect to the first direction (X-axis direction).

FIG. 9 illustrates an embodiment where each of the first emission area EA1, the second emission area EA2, the third emission area EA3, and the fourth emission area EA4 has a rhombic or rectangular shape in a plan view, but an embodiment is not limited to that illustrated in of FIG. 9. Alternatively, each of the first emission area EA1, the second emission area EA2, the third emission area EA3, and the fourth emission area EA4 may have a polygonal shape other than the rectangular shape, a circular shape, or an elliptical shape in a plan view.

FIG. 9 illustrates an embodiment where an area of the third emission area EA3 is the greatest and areas of the second emission area EA2 and the fourth emission area EA4 are the smallest on the assumption that the first color, the second color, and the third color are red, green, and blue, respectively, but an embodiment is not limited to that illustrated in FIG. 9.

In an embodiment, the display panel 100 may further include a color filter layer disposed on the touch sensing unit 200.

In FIG. 10, for convenience of illustration, the touch driving electrodes TE, the receiving electrodes RE, the bridge electrodes BE, the first emission areas EA1, the second emission areas EA2, the third emission areas EA3, and the fourth emission areas EA4 are denoted by dotted lines, and the color filter layer CFL is denoted by a solid line.

Referring to FIG. 10, the color filter layer CFL may include first color filters CF1 corresponding to the first emission areas EA1, second color filters CF2 corresponding to the second emission areas EA2 and the fourth emission areas EA4, and third color filters CF3 corresponding to the third emission areas EA3.

The first color filter CF1 may overlap the first emission area EA1 in a third direction (Z-axis direction), and may not overlap the second emission area EA2, the third emission area EA3, and the fourth emission area EA4 in the third direction (Z-axis direction). Accordingly, light of the first emission area EA1 may be emitted to the outside of the display panel 100 through the first color filter CF1.

The second color filters CF2 may overlap the second emission area EA2 and the fourth emission area EA4 in the third direction (Z-axis direction), and may not overlap the first emission area EA1 and the third emission area EA3 in the third direction (Z-axis direction). Accordingly, light of the second emission area EA2 and the fourth emission area EA4 may be emitted to the outside of the display panel 100 through the second color filter CF2.

The third color filter CF3 may overlap the third emission area EA3 in the third direction (Z-axis direction), and may not overlap the first emission area EA1, the second emission area EA2, and the fourth emission area EA4 in the third direction (Z-axis direction). Accordingly, light of the third emission area EA3 may be emitted to the outside of the display panel 100 through the third color filter CF3.

Referring to FIG. 11, an embodiment of the display panel 100 includes a support substrate 110, a circuit array 120 on the support substrate 110, a via layer 130 on the circuit array 120, an emitting array 140 on the via layer 130, and a sealing structure 150 on the emitting array 140.

In such an embodiment, the touch sensing unit 200 may be disposed on the sealing structure 150 of the display panel 100.

In such an embodiment, the color filter layer CFL and an optical layer OCL may be disposed on the touch sensing unit 200.

The support substrate 110 may include or be made of a material having flexible characteristics to be able to be bent, folded, or rolled.

The support substrate 110 may include or be made of an insulating material such as a polymer resin. In an embodiment, for example, the support substrate 110 may be made of polyimide.

The circuit array 120 includes a plurality of pixel driving circuits PDC each corresponding to the plurality of main pixel areas MPX and the plurality of additional pixel areas APX, and each of the plurality of pixel driving circuits PDC includes a driving transistor DTR connected to an emitting device EMD.

The circuit array 120 may include a barrier layer 121 covering the support substrate 110.

The barrier layer 121 is a film for protecting transistors of the circuit array 120 and emitting layers 143 of the emitting array 140 from moisture permeating through the support substrate 110 vulnerable to moisture permeation. The barrier layer 121 may include a plurality of inorganic films that are alternately stacked. In an embodiment, for example, the barrier layer 121 may be formed as or defined by multiple films in which inorganic films selected from a silicon nitride layer, a silicon oxynitride layer, a silicon oxide layer, a titanium oxide layer, and an aluminum oxide layer are alternately stacked one on another.

The driving transistor DTR may be disposed on the barrier layer 121.

The driving transistor DTR may include an active layer ACT disposed on the barrier layer 121 and a gate electrode G disposed on a gate insulating layer 122 covering the active layer ACT and overlapping a channel region C of the active layer ACT.

The active layer ACT may include the channel region C in which a movement path of carriers is formed and a source region SD1 and a drain region SD2 in contact with opposing sides of the channel region C.

The active layer ACT may include polycrystalline silicon, single crystal silicon, low-temperature polycrystalline silicon, amorphous silicon, or an oxide semiconductor.

The source region SD1 and the drain region SD2 of the active layer ACT may be regions doped with ions or impurities to have conductivity.

The gate insulating layer 122 may be defined by or formed as an inorganic film including a silicon nitride layer, a silicon oxynitride layer, a silicon oxide layer, a titanium oxide layer, or an aluminum oxide layer.

The circuit array 120 may further include a capacitor electrode CAE disposed on a first interlayer insulating layer 123 covering the gate electrode G and at least partially overlapping the gate electrode G.

In an alternative embodiment, unlike illustrated in FIG. 11, the capacitor electrode CAE may be defined by or formed as a pattern disposed in a same layer as the gate electrode G and connected to the gate electrode G. Here, when two elements are disposed in a same layer, the two elements may be disposed directly on a same layer or defined by portions of a same layer.

Each of the gate electrode G and the capacitor electrode CAE may be defined by or formed as a single layer or multiple layers, each including or made of molybdenum (Mo), aluminum (Al), chromium (Cr), gold (Au), titanium (Ti), nickel (Ni), neodymium (Nd), and copper (Cu), or alloys thereof.

The first interlayer insulating layer 123 may be defined by or formed as an inorganic film including a silicon nitride layer, a silicon oxynitride layer, a silicon oxide layer, a titanium oxide layer, or an aluminum oxide layer. Alternatively, the first interlayer insulating layer 123 may have a structure in which a plurality of inorganic films are stacked one on another.

The circuit array 120 may further include a first anode connection electrode ANDE1 disposed on a second interlayer insulating layer 124 covering the capacitor electrode CAE.

The first anode connection electrode ANDE1 may be connected to the drain region D of the active layer ACT of the driving transistor DTR through a first connection contact hole ANCT1 defined through the second interlayer insulating layer 124, the first interlayer insulating layer 123, and the gate insulating layer 122.

The via layer 130 may include a first planarization layer 131 covering the first anode connection electrode ANDE1 and a second planarization layer132 covering a second anode connection electrode ANDE2 disposed on the first planarization layer 131.

Each of the first planarization layer 131 and the second planarization layer132 may be defined by or formed as an organic film including or made of an acrylic resin, an epoxy resin, a phenolic resin, a polyamide resin, a polyimide resin, or the like.

The second anode connection electrode ANDE2 may be connected to the first anode connection electrode ANDE1 through a second connection contact hole ANCT2 defined through the first planarization layer 131.

Each of the first anode connection electrode ANDE1 and the second anode connection electrode ANDE2 may be defined by or formed as a single layer or multiple layers including or made of molybdenum (Mo), aluminum (Al), chromium (Cr), gold (Au), titanium (Ti), nickel (Ni), neodymium (Nd), and copper (Cu), or alloys thereof.

The emitting array 140 includes a plurality of emitting devices EMD each corresponding to the plurality of main pixel areas MPX and the plurality of additional pixel areas APX.

In an embodiment, as described above, each of the plurality of main pixel areas MPX and the plurality of additional pixel areas APX may be one of the first emission area EA1 that emits the light of the first color, the second emission area EA2 that emits the light of the second color, the third emission area EA3 that emits the light of the third color, and the fourth emission area EA4 parallel to the second emission area EA2 in the second direction (Y-axis direction) and that emits the light of the second color.

In such an embodiment, the emitting array 140 includes the plurality of emitting devices EMD each corresponding to the first emission area EA1, the second emission area EA2, the third emission area EA3, and the fourth emission area EA4.

Each of the plurality of emitting devices EMD includes a pixel electrode 141 disposed on the via layer 130, a common electrode 144 facing the pixel electrode 141, and an emitting layer 143 interposed between the pixel electrode 141 and the common electrode 144.

In such an embodiment, the emitting array 140 may include the pixel electrodes 141 and a pixel defining layer 142 disposed on the via layer 130, the emitting layers 143 disposed on the pixel electrodes 141, and the common electrode 144 disposed on the pixel defining layer 142 and the emitting layers 143.

The emitting array 140 includes a plurality of pixel electrodes 141 each corresponding to the first emission area EA1, the second emission area EA2, the third emission area EA3, and the fourth emission area EA4.

The pixel electrode 141 may be connected to the second anode connection electrode ANDE2 through a third connection contact hole ANCT3 defined through the second planarization layer132.

The pixel electrode 141 may include or be made of a metal material having high reflectivity, such as a stacked structure (Ti/Al/Ti) of aluminum and titanium, a stacked structure (ITO/A1/ITO) of aluminum and indium tin oxide (ITO), an APC alloy, and a stacked structure (ITO/APC/ITO) of an APC alloy and ITO. The APC alloy is an alloy of silver (Ag), palladium (Pd), and copper (Cu).

The pixel defining layer 142 is disposed on the via layer 130, corresponds to spaces between the first emission area EA1, the second emission area EA2, the third emission area EA3, and the fourth emission area EA4, and covers edges of each of the plurality of pixel electrodes 141.

The pixel defining layer 142 may be defined by or formed as an organic film made of an acrylic resin, an epoxy resin, a phenolic resin, a polyamide resin, a polyimide resin, or the like.

The emitting array 140 includes a plurality of emitting layers 143 each corresponding to the first emission area EA1, the second emission area EA2, the third emission area EA3, and the fourth emission area EA4.

The emitting layer 143 may include or be made of an organic emitting material.

Each of the plurality of emitting devices EMD may further include a hole transport layer (not illustrated) disposed between the pixel electrode 141 and the emitting layer 143 and an electron transport layer (not illustrated) disposed between the emitting layer 143 and the common electrode 144.

The common electrode 144 entirely corresponds to the first emission area EA1, the second emission area EA2, the third emission area EA3, and the fourth emission area EA4, and is disposed on the pixel defining layer 142 and the emitting layers 143.

The common electrode 144 may include or be made of a transparent conductive material (TCO) such as ITO or indium zinc oxide (IZO) capable of transmitting light or a semi-transmissive conductive material such as magnesium (Mg), silver (Ag), or an alloy of magnesium (Mg) and silver (Ag). In an embodiment where the common electrode 144 include or is made of the semi-transmissive conductive material, an improvement in light emission efficiency due to a micro cavity structure may be provided.

The sealing structure 150 may include a first sealing layer 151 disposed on the emitting array 140 and including an inorganic insulating material, a second sealing layer 152 disposed on the first sealing layer 151 and including an organic insulating material, and a third sealing layer 153 disposed on the first sealing layer 151, covering the second sealing layer 152, and including an inorganic insulating material.

The third sealing layer 153 may be in contact with an edge of the first sealing layer 151. That is, the second sealing layer 152 may be encapsulated between the first sealing layer 151 and the third sealing layer 153.

Permeation of oxygen or moisture into the emitting array 140 may be prevented by a stacked structure of the first sealing layer 151, the second sealing layer 152, and the third sealing layer 153.

In addition, damage to the emitting array 140 due to foreign materials such as dust may be prevented by the second sealing layer 152.

Each of the first sealing layer 151 and the third sealing layer 153 may have a structure in which inorganic films, each including a silicon nitride layer, a silicon oxynitride layer, a silicon oxide layer, a titanium oxide layer, or an aluminum oxide layer are stacked one on another.

The second sealing layer 152 may be defined by or formed as an organic film including an acrylic resin, an epoxy resin, a phenolic resin, a polyamide resin, a polyimide resin, or the like.

The touch sensing unit 200 may be disposed on the third sealing layer 153 of the sealing structure 150.

The touch sensing unit 200 includes the touch driving electrodes TE, the receiving electrodes RE, and the bridge electrodes BE.

The touch driving electrode TE and the receiving electrode RE are disposed at the same layer and are spaced apart from each other.

The bridge electrode BE is disposed in a different layer from the touch driving electrode TE and the receiving electrode RE to be insulated from the receiving electrode RE.

The touch sensing unit 200 may further include a first touch insulating layer 201 covering the third sealing layer 153.

The bridge electrodes BE may be disposed on the first touch insulating layer 201.

The first touch insulating layer 201 may be defined by or formed as an inorganic film including a silicon nitride layer, a silicon oxynitride layer, a silicon oxide layer, a titanium oxide layer, or an aluminum oxide layer.

The bridge electrode BE may be defined by or formed as a single layer or multiple layers, each including or made of any one of molybdenum (Mo), aluminum (Al), chromium (Cr), gold (Au), titanium (Ti), nickel (Ni), neodymium (Nd), and copper (Cu), or alloys thereof.

The touch driving electrodes TE and the receiving electrodes RE may be disposed on a second touch insulating layer 202 covering the bridge electrodes BE.

The second touch insulating layer 202 may be defined by or formed as an inorganic film including a silicon nitride layer, a silicon oxynitride layer, a silicon oxide layer, a titanium oxide layer, or an aluminum oxide layer. Alternatively, the second touch insulating layer 202 may be defined by or formed as an organic film made of an acrylic resin, an epoxy resin, a phenolic resin, a polyamide resin, a polyimide resin, or the like.

The dummy patterns DE disposed inside each of the touch driving electrodes TE and the receiving electrodes RE, the first touch driving lines TL1 and the second touch driving lines TL2 connected to the touch driving electrodes TE, and the receiving lines RL connected to the receiving electrodes RE may also be disposed on the second touch insulating layer 202, together with the touch driving electrodes TE and the receiving electrodes RE.

The touch driving electrode TE may be electrically connected to the bridge electrode BE through a touch contact hole TCNT1 defined through the second touch insulating layer 202.

Each of the touch driving electrodes TE and the receiving electrodes RE, the dummy patterns DE, the first touch driving lines TL1 and the second touch driving lines TL2, and the receiving lines RL disposed on the second touch insulating layer 202 may have a structure including a low reflection layer. Due to the low reflection layer, outside light reflection that light incident from the outside and reflected within the display panel 100 is emitted may be reduced.

The touch sensing unit 200 may further include a third touch insulating layer 203 disposed on the second touch insulating layer 202 and covering the touch driving electrodes TE and the receiving electrodes RE, the dummy patterns DE, the first touch driving lines TL1 and the second touch driving lines TL2, and the receiving lines RL to provide a flat surface thereon.

The third touch insulating layer 203 may be defined by or formed as an organic film made of an acrylic resin, an epoxy resin, a phenolic resin, a polyamide resin, a polyimide resin, or the like.

The color filter layer CFL may include the first color filters CF1 corresponding to the first emission areas EA1, the second color filters CF2 corresponding to the second emission areas EA2 and the fourth emission areas EA4, and the third color filters CF3 corresponding to the third emission areas EA3.

The first color filter CF1 may transmit light of a first wavelength range corresponding to the first color, and may overlap the first emission area EA1 in the third direction (Z-axis direction).

In an embodiment, for example, the first wavelength range may be about 600 nm to about 750 nm, and the first color may be red.

The second color filter CF2 may transmit light of a second wavelength range corresponding to the second color, and may overlap the second emission area EA2 in the third direction (Z-axis direction).

In an embodiment, for example, the second wavelength range may be about 480 nm to about 560 nm, and the second color may be green.

The third color filter CF3 may transmit light of a third wavelength range corresponding to the third color, and may overlap the third emission area EA3 in the third direction (Z-axis direction).

In an embodiment, for example, the third wavelength range may be about 370 nm to about 460 nm, and the third color may be blue.

In an embodiment, only the first color filter CF1 may overlap each of the touch driving electrode TE, the receiving electrode RE, the bridge electrode BE, and the touch contact hole TCNT1 of the touch sensing unit 200 in the third direction (Z-axis direction). In such an embodiment, the second color filter CF2 and the third color filter CF3 may not overlap each of the touch driving electrode TE, the receiving electrode RE, the bridge electrode BE, and the touch contact hole TCNT1.

In an embodiment, for example, as illustrated in FIG. 11, edges of the first color filter CF1 may be covered with any one of the second color filter CF2 and the third color filter CF3. However, an embodiment illustrated in FIG. 11 is only an example, and an embodiment is not limited to that illustrated in FIG. 11.

In an embodiment, as described above, each of the touch driving electrodes TE and the receiving electrodes RE, the dummy patterns DE, the first touch driving lines TL1 and the second touch driving lines TL2, and the receiving lines RL may include the low reflection layer. Accordingly, even though a black matrix (not illustrated) corresponding to the spaces between the first emission area EA1, the second emission area EA2, the third emission area EA3, and the fourth emission area EA4 is not disposed, an increase in visibility of the touch driving electrode TE and the receiving electrode RE, the dummy pattern DE, the first touch driving line TL1 and the second touch driving line TL2, and the receiving line RL due to the outside light reflection may be prevented.

In an embodiment, a polarizing plate (not illustrated) for reducing the outside light reflection may not be disposed, and thus, light emission efficiency may be improved.

Next, various embodiments of the dam structure DS including the first dam structure DM1 and the second dam structure DM2 will be described.

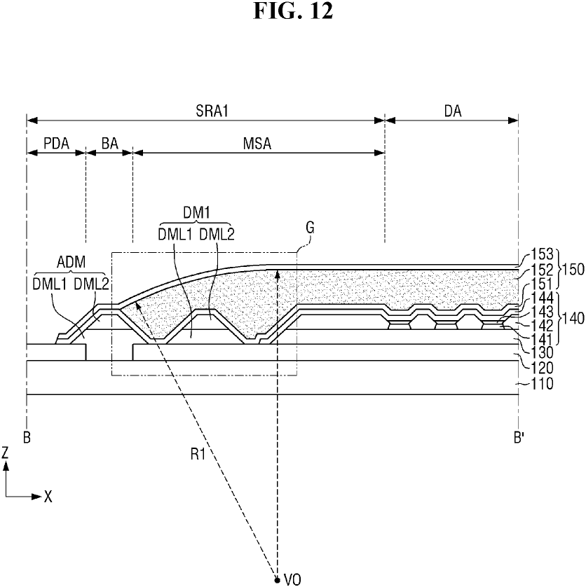

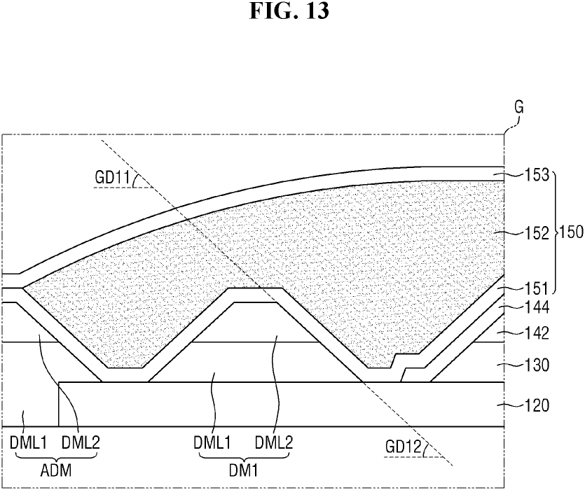

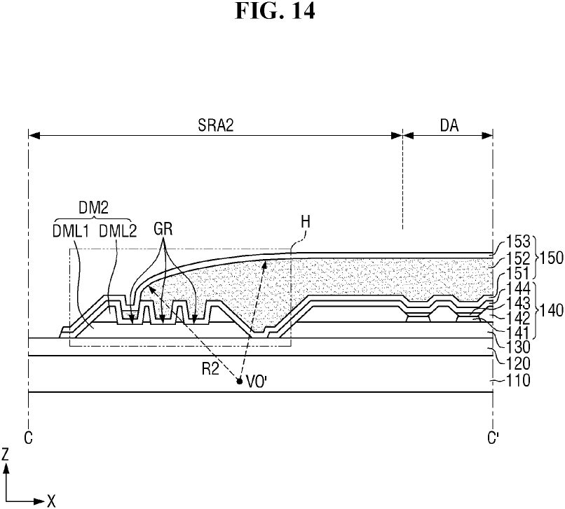

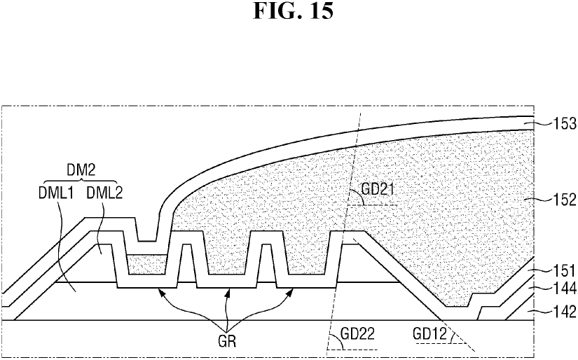

FIG. 12 is a cross-sectional view illustrating an embodiment of a first dam structure corresponding to line B-B′ of FIG. 6. FIG. 13 is an enlarged view illustrating portion G of FIG. 12 in detail. FIG. 14 is a cross-sectional view illustrating an embodiment of a second dam structure corresponding to line C-C′ of FIG. 6. FIG. 15 is an enlarged view illustrating portion H of FIG. 14 in detail.

Referring to FIGS. 12 and 14, in an embodiment, each of a first dam structure DM1 and a second dam structure DM2 included in a dam structure DS may have a structure in which a first dam layer DML1 and a second dam layer DML2 are stacked one on another.

The first dam layer DML1 may be defined by or formed as a same layer as the via layer 130.

The second dam layer DML2 may be defined by or formed as a same layer as the pixel defining layer 142.

The first sealing layer 151 of the sealing structure 150 may be disposed in at least a portion of each of the first surrounding area SRA1 and the second surrounding area SRA2 of the non-display area NDA in contact with the display area DA as well as in the display area DA.

In an embodiment, the first sealing layer 151 may cover the first dam structure DM1 of the first surrounding area SRA1 and the second dam structure DM2 of the second surrounding area SRA2.

In an embodiment, the first sealing layer 151 may be disposed on both the display area DA and the non-display area NDA of the support substrate 110.

The first sealing layer 151 may be provided by depositing an inorganic insulating material including at least one selected from a silicon nitride layer, a silicon oxynitride layer, a silicon oxide layer, a titanium oxide layer, and an aluminum oxide layer.

The second sealing layer 152 of the sealing structure 150 is disposed at least in the display area DA.

The second sealing layer 152 may include or be made of an organic film such as an acrylic resin, an epoxy resin, a phenolic resin, a polyamide resin, or a polyimide resin.

In an embodiment, a process of disposing such a second sealing layer 152 may include a process of dropping a liquid organic insulating material on the display area DA of the first sealing layer 151, a process of waiting for a drop material of the liquid organic insulating material to gradually spread widely to the surroundings for a predetermined grace time, and a process of curing the spreading organic insulating material. In such an embodiment, in the process of waiting for the drop material of the liquid organic insulating material to gradually spread to the surroundings for the predetermined grace time, the liquid organic insulating material dropped at least once on the display area DA of the first sealing layer 151 gradually spreads to the surroundings and is blocked by side portions of the first dam structure DM1 and the second dam structure DM2. In such an embodiment, the first dam structure DM1 and the second dam structure DM2 function as barriers for limiting an area in which the drop material of the liquid organic insulating material constituting the second sealing layer 152 spreads.

Accordingly, in an embodiment, the second sealing layer 152 is surrounded by the first dam structure DM1 and the second dam structure DM2. In such an embodiment, the second sealing layer 152 may be provided in a shape in which it includes a first side portion corresponding to the first dam structure DM1 and a second side portion corresponding to the second dam structure DM2.

The drop material of the liquid organic insulating material widely spreads to the surroundings based on kinetic energy according to the drop and surface tension of a liquid. In addition, when the drop material of the liquid organic insulating material encounters a step due to the first dam structure DM1 while spreading to the first surrounding area SRA1 of the non-display area NDA, a flow of the drop material is hindered by the step due to the first dam structure DM1, such that an amount of the spread drop material is gradually decreased.

Accordingly, the second sealing layer 152 includes curved side portions or side portions having a curved cross section.

In an embodiment, as illustrated in FIG. 8, the sensor line SENL of the touch sensing unit 200 disposed on the sealing structure 150 extends from the second surrounding area SRA2 to the pad area PDA of the first surrounding area SRA1. Accordingly, in such an embodiment, when a slope of the first side portion of the second sealing layer 152 is steep, a process error may occurs when the sensor line SENL of the touch sensing unit 200 is disposed, such that a possibility of disconnection of the sensor line SENL may increase.

According to an embodiment for preventing disconnection of the sensor line SENL, as illustrated in FIG. 12, the first side portion of the second sealing layer 152 corresponding to the first dam structure DM1 of the first surrounding area SRA1 climbs over the dam structure DM1 and further extends. In addition, a height (or thickness) of the first side portion with respect to the support substrate 110 gradually decreases as the first side portion becomes closer to an edge of the support substrate 110.

That is, the first side portion of the second sealing layer 152 may have a cross section with a first curvature (1/R1) corresponding to a predetermined first radius of curvature R1. In FIG. 12, VO illustratively denotes an imaginary center of curvature corresponding to the first curvature (1/R1) of the first side portion.

Referring to FIG. 13, in an embodiment, the first dam structure DM1 includes a side surface with a gentle slope not to significantly hinder the flow of the drop material, to be covered with the first side portion of the second sealing layer 152.

In an embodiment, for example, in the first dam structure DM1, a gradient GD11 of the side surface with respect to an upper surface and a gradient GD12 of the side surface with respect to a lower surface may be less than about 45°. In such an embodiment where the side surface of the first dam structure DM1 has a curved shape, the gradient GD11 of the side surface with respect to the upper surface and the gradient GD12 of the side surface with respect to the lower surface may be different from each other. In an embodiment, the gradient GD11 of the side surface with respect to the upper surface and the gradient GD12 of the side surface with respect to the lower surface may be 0° or more.

In such an embodiment, the flow of the drop material of the liquid organic insulating material may go over the step due to the first dam structure DM1, and thus, the first side portion of the second sealing layer 152 may cover the first dam structure DM1 to have the cross section with the first curvature (1/R1) that is gentle.

In an embodiment, as illustrated in FIG. 12, the display panel 100 may further include an assistant dam ADM for blocking the flow of the drop material that went over the first dam structure DM1.

The assistant dam ADM may include a first dam layer DML1 defined by or formed as a same layer as the via layer 130 and a second dam layer DML2 defined by or formed as a same layer as the pixel defining layer 142, similar to the first dam structure DM1.

Since the first dam layer DML1 and the second dam layer DML2 are organic films of which the occurrence of crack defects due to bending stress is relatively less, the assistant dam ADM may be disposed in the bending area BA. Therefore, the second sealing layer 152 may be prevented from extending to the pad area PDA.

The third sealing layer 153 may be in contact with the edge of the first sealing layer 151 on the assistant dam ADM. In an embodiment, a contact point between the first sealing layer 151 and the third sealing layer 153 is spaced apart from the support substrate 110 by the assistant dam ADM, and may thus be subjected to relatively small bending stress. In an embodiment, in consideration of a crack due to the bending stress, portions of the insulating films of the circuit array 120 corresponding to the bending area BA may be removed.

In an embodiment, as illustrated in FIG. 8, the sensor line SENL of the touch sensing unit 200 may be disposed in an area between the touch sensing area TSA and the second dam structure DM2 in the second surrounding areas SRA2.

In an embodiment, the touch sensing unit 200 generates sensing signals based on mutual capacitance between the touch driving electrodes TE, the receiving electrodes RE, the dummy patterns DE, and the bridge electrodes BE. In such an embodiment, the mutual capacitance is affected by a thickness of the insulating film disposed below the touch sensing unit 200, in particular, a thickness of the second sealing layer 152.

Therefore, in a case where the second side portion of the second sealing layer 152 corresponding to the second dam structure DM2 disposed in the second surrounding area SRA2 has a thickness (i.e., a height or thickness of the second sealing layer 152 with respect to the support substrate 110) that is gradually decreased in a relatively great width, mutual capacitance generated at an edge of the touch sensing area TSA may be different from that at the center of the touch sensing area TSA. In this case, sensing sensitivity at the edge of the touch sensing area TSA may be decreased.

According to an embodiment for preventing sensing sensitivity at the edge of the touch sensing area TSA from being decreased, as illustrated in FIG. 14, the second side portion of the second sealing layer 152 corresponding to the second dam structure DM2 of the second surrounding area SRA2 has a thickness that is rapidly decreased at a relatively small width.

In such an embodiment, the second side portion of the second sealing layer 152 may have a cross section with a second curvature (1/R2) greater than the first curvature (1/R1) of the first side portion. In FIG. 14, R2 illustratively denotes a second radius of curvature corresponding to a curvature shape of the second side portion of the second sealing layer 152, and VO’ illustratively denotes an imaginary center of curvature corresponding to the second radius of curvature R2 of the second side portion.

In such an embodiment, a plurality of grooves GR may be defined in in an upper surface of the second dam structure DM2 through at least portions of the second dam structure DM2 to extend in parallel with each other.

In an embodiment, for example, the plurality of grooves GR may extend through at least portions of the second dam layer DML2 of the second dam structure DM2. That is, the plurality of grooves GR may extend through at least portions of the first dam layer DML1 of the second dam structure DM2 as well as through the second dam layer DML2 of the second dam structure DM2 without exposing a conductive pattern of the circuit array 120 disposed below the second dam structure DM2.

Referring to FIG. 15, in an embodiment, the plurality of grooves GR include side surfaces having a higher gradient than the second dam structure DM2 to more strongly hinder the flow of the drop material of the liquid organic insulating material for disposing the second sealing layer 152.

In an embodiment, for example, in the plurality of grooves GR, a gradient GD21 of the side surface with respect to an upper surface and a gradient GD22 of the side surface with respect to a lower surface may be in a range of about 45° to about 90°. In an embodiment where the side surfaces of the plurality of grooves GR have a curved shape, the gradient GD21 of the side surface with respect to the upper surface and the gradient GD22 of the side surface with respect to the lower surface may be different from each other.

In an embodiment, since the second dam structure DM2 is provided together with the first dam structure DM1 by a same process as the first dam structure DM1, like the first dam structure DM1, in the second dam structure DM2, a gradient GD11 of a side surface with respect to an upper surface and a gradient GD12 of the side surface with respect to a lower surface may be less than about 45°.

As described above, according to an embodiment, the plurality of grooves GR including the side surfaces having a relatively high gradient in a range of about 45° to about 90° are disposed in the second dam structure DM2. Therefore, due to an increase in volume and an increase in planar contact angle by the plurality of grooves GR, the flow of the drop material of the liquid organic insulating material may be effectively blocked in the second dam structure DM2 in which the plurality of grooves GR are defined.

Therefore, as illustrated in FIG. 14, the second side portion of the second sealing layer 152 corresponding to the second dam structure DM2 may have the cross section with the second curvature (1/R2) greater than the first curvature (1/R1) of the first side portion. In such an embodiment, a height or thickness of the second side portion with respect to the support substrate 110 is rapidly decreased as the second side portion becomes closer to the second dam structure DM2.

Therefore, in such an embodiment, the decrease in the sensing sensitivity occurring because the mutual capacitance at the edge of the touch sensing area TSA adjacent to the second surrounding area SRA2 is different from that at the center of the touch sensing area TSA may be effectively prevented. In such an embodiment, a portion of the sensor line SENL disposed in the second surrounding area SRA2 is disposed on the second sealing layer 152, and thus, a disconnection defect due to a step of the second sealing layer 152 may be prevented.

In such an embodiment, since the second side portion of the second sealing layer 152 corresponding to the second dam structure DM2 has the cross section with the second curvature 1/R2 higher than that of the first side portion, the second side portion may have a smaller width than the first side portion according to a difference between the first curvature (1/R1) and the second curvature (1/R2).

In such an embodiment, since the flow of the drop material of the liquid organic insulating material may be effectively blocked by one second dam structure DM due to the plurality of grooves GR defined therein, such that a width of the second surrounding area SRA2 may be decreased by not providing a plurality of second dam structures.

In such an embodiment, a width of the second side portion of the second sealing layer 152 disposed in the second surrounding area SRA2 may be decreased. Therefore, the width of the second surrounding area SRA2 of the non-display area NDA may be decreased, and accordingly, a quality of the display panel 100 such as resolution, an aspect ratio, and aesthetics may be improved.

In such an embodiment, the flow of the drop material of the liquid organic insulating material may be easily confirmed by the plurality of grooves GR into which the drop material of the liquid organic insulating material flows.

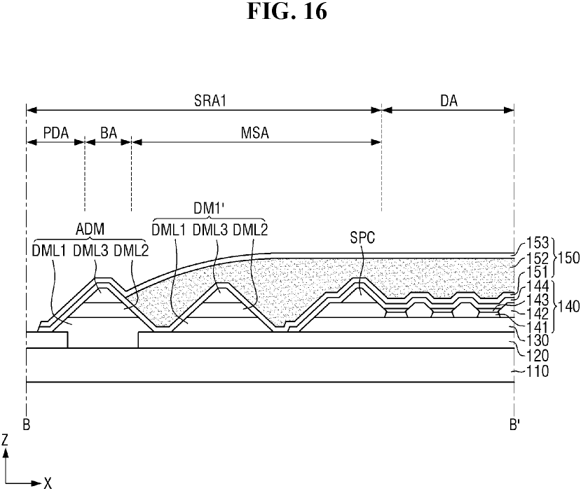

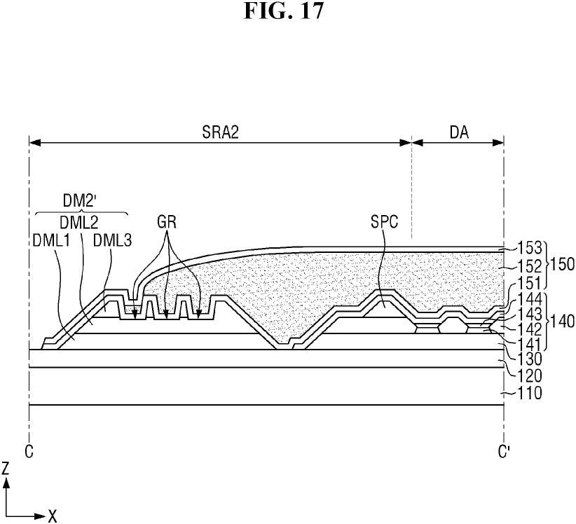

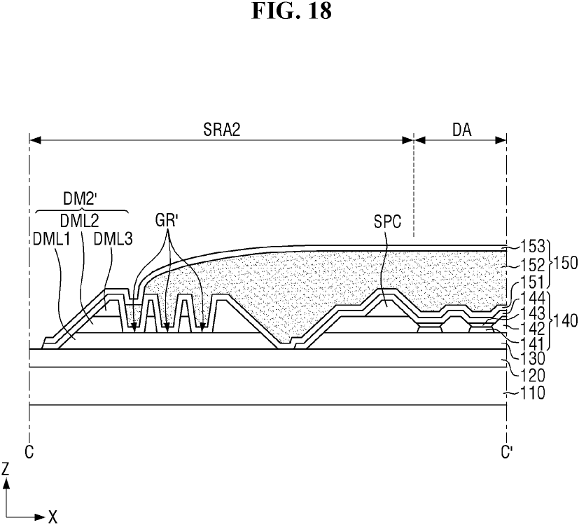

FIG. 16 is a cross-sectional view illustrating an alternative embodiment of a first dam structure corresponding to line B-B′ of FIG. 6. FIG. 17 is a cross-sectional view illustrating an alternative embodiment of a second dam structure corresponding to line C-C′ of FIG. 6. FIG. 18 is a cross-sectional view illustrating another alternative embodiment of a second dam structure corresponding to line C-C′ of FIG. 6.

Referring to FIGS. 16 to 18, an alternative embodiment of a dam structure DS is the same as the dam structure according to the embodiment described with reference to FIGS. 12 to 15 except that each of a first dam structure DM1′ and a second dam structure DM2′ further includes a third dam player DML3 disposed on the second dam layer DML2. The same or like elements shown in FIGS. 16 to 18 are labeled with the same reference characters as used above to describe the embodiment shown in FIGS. 12 to 15, and any repetitive detailed description thereof will hereinafter be omitted or simplified.

Referring to FIGS. 16 and 17, in an embodiment, an emitting array 140 of a display panel 100 further includes spacers SPC disposed on the pixel defining layer 142 and corresponding to portions of spaces between the plurality of main pixel areas MPX and the plurality of additional pixel areas APX.

The spacers SPC are provided to support a deposition mask (not illustrated) used for disposing the emitting layers 143 corresponding to respective colors, such as the first emission area EA1, the second emission area EA2, the fourth emission area EA4, and the third emission area EA3, apart from the pixel electrodes 141. Damage to the pixel electrodes 141 and damage to the pixel defining layer 142 due to physical impact by the deposition mask may be prevented by such spacers SPC.

The spacers SPC are provided to support the deposition mask, and may be disposed on the pixel defining layer 142 at intervals enough to prevent a sag of the deposition mask.

The space SPC may be defined by or formed as an organic film made of an acrylic resin, an epoxy resin, a phenolic resin, a polyamide resin, a polyimide resin, or the like, similar to the pixel defining layer 142.

In an embodiment, the spacers SPC may be provided by a same mask process as the pixel defining layer 142 through a patterning process using a halftone mask.

in such an embodiment where the emitting array 140 includes the spacers SPC disposed on the pixel defining layer 142, the common electrode 144 is disposed to further cover the spacers SPC as well as the pixel defining layer 142 and the emitting layers 143.

According to an embodiment, each of the first dam structure DM1′ and the second dam structure DM2′ included in the dam structure DS may be provided in a structure in which a first dam layer DML1 defined by or formed as a same layer as the via layer 130, a second dam layer DML2 defined by or formed as a same layer as the pixel defining layer 142, and a third dam layer DML3 defined by or formed as a same layer as the spacer SPC are stacked one on another.

In such an embodiment, as illustrated in FIG. 17, a plurality of grooves GR disposed in the second dam structure DM2′ may extend through at least portions of the third dam layer DML3.

Alternatively, as illustrated in FIG. 18, a plurality of grooves GR′ may be provided to extend through the third dam layer DML3 and the second dam layer DML2. In such an embodiment, the reliability of protection of a conductive pattern of the circuit array 120 disposed below the second dam structure DM2 may be improved.

As described above, according to an embodiment, a thickness of each of the first dam structure DM1′ and the second dam structure DM2′ may be further secured by the third dam layer DML3, which is defined by a same layer as the spacer SPC, and thus, a process of disposing the second sealing layer 152 may be performed more precisely.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display panel comprising:
a support substrate including a display area including a plurality of pixel areas which emits light for image display and a non-display area disposed around the display area;
an emitting array disposed on the support substrate and including a plurality of emitting devices corresponding to the plurality of pixel areas;
a first dam structure disposed in a first surrounding area in contact with one side of the display area in the non-display area;
a second dam structure disposed in a second surrounding area in contact with another side of the display area in the non-display area and having a same thickness as the first dam structure; and
a sealing structure covering the emitting array,
wherein the sealing structure includes:
a first sealing layer disposed on the emitting array and including an inorganic insulating material;
a second sealing layer disposed on the first sealing layer and including an organic insulating material; and
a third sealing layer disposed on the first sealing layer, covering the second sealing layer, and including the inorganic insulating material,
wherein the third sealing layer is in contact with an edge of the first sealing layer, and
wherein the second sealing layer includes a first side portion corresponding to the first dam structure and having a cross section with a first curvature and a second side portion corresponding to the second dam structure and having a cross section with a second curvature greater than the first curvature.

2. The display panel of claim 1, wherein a plurality of grooves is defined in an upper surface of the second dam structure through at least portions of the second dam structure to extend in parallel with each other.

3. The display panel of claim 2, wherein a gradient of a side surface of the second dam structure defining the plurality of grooves with respect to the upper surface or a lower surface of the second dam structure is in a range of about to about 90°.

4. The display panel of claim 2, wherein
the first side portion covers the first dam structure, and
a height of the first side portion with respect to the support substrate gradually decreases as the first side portion becomes closer to an edge of the support substrate corresponding to the first surrounding area.

5. The display panel of claim 4, wherein a gradient of a side surface of the first dam structure is less than about 45°.

6. The display panel of claim 2, wherein
a height of the first side portion with respect to the support substrate gradually decreases with a first slope corresponding to the first curvature as the first side portion becomes more distant from the display area,
a height of the second side portion with respect to the support substrate decreases with a second slope corresponding to the second curvature greater than the first curvature and greater than the first slope as the second side portion becomes more distant from the display area, and
a width of the second side portion is smaller than a width of the first side portion.

7. The display panel of claim 6, wherein
the display area has a rectangular shape including first and second sides opposing each other and third and fourth sides in contact with the first and second sides and opposing each other,
the first surrounding area is in contact with the first side of the display area, and
the second surrounding area is in contact with the second side, the third side, and the fourth side of the display area.

8. The display panel of claim 2, further comprising:
a circuit array disposed on the support substrate and including a plurality of pixel driving circuits corresponding to the plurality of pixel areas and connected to the plurality of emitting devices; and
a via layer covering the circuit array,
wherein the emitting array includes:
a plurality of first electrodes disposed on the via layer and corresponding to the plurality of pixel areas;
a pixel defining layer disposed on the via layer, between the plurality of pixel areas, and covering edges of each of the plurality of first electrodes;
a plurality of emitting layers disposed on the plurality of first electrodes, respectively; and
a second electrode disposed on the pixel defining layer and the plurality of emitting layers and corresponding to the plurality of pixel areas, and each of the first dam structure and the second dam structure includes:
a first dam layer defined by a same layer as the via layer; and
a second dam layer disposed on the first dam layer and defined by a same layer as the pixel defining layer.

9. The display panel of claim 8, wherein the plurality of grooves is defined through at least portions of the second dam layer of the second dam structure.

10. The display panel of claim 8, wherein
the emitting array further includes a spacer disposed on the pixel defining layer between the plurality of pixel areas,
each of the first dam structure and the second dam structure further includes a third dam layer disposed on the second dam layer and defined by a same layer as the spacer, and
the plurality of grooves is defined through at least portions of the third dam layer of the second dam structure.

11. A display apparatus comprising:
a display panel which emits light for image display; and
a touch sensing unit disposed on the display panel,
wherein the display panel includes:
a support substrate including a display area including a plurality of pixel areas for the image display and a non-display area disposed around the display area;
an emitting array disposed on the support substrate and including a plurality of emitting devices corresponding to the plurality of pixel areas;
a first dam structure disposed in a first surrounding area in contact with one side of the display area in the non-display area; and
a second dam structure disposed in a second surrounding area in contact with the other side of the display area in the non-display area, wherein a plurality of grooves is defined in an upper surface of the second dam structure through at least portions of the second dam structure to extend in parallel with each other; and a sealing structure covering the emitting array,
wherein a gradient of a side surface of the second dam structure defining the plurality of grooves with respect to the upper surface or a lower surface of the second dam structure is in a range of about 45° to about 90°.

12. The display apparatus of claim 11, wherein
the sealing structure includes:
a first sealing layer disposed on the emitting array and including an inorganic insulating material;
a second sealing layer disposed on the first sealing layer and including an organic insulating material; and
a third sealing layer disposed on the first sealing layer, covering the second sealing layer, and including the inorganic insulating material,
wherein the third sealing layer is in contact with an edge of the first sealing layer, and
the second sealing layer is surrounded by the first dam structure and the second dam structure.

13. The display apparatus of claim 12, wherein the second sealing layer includes:
a first side portion corresponding to the first dam structure and having a cross section with a first curvature; and
a second side portion corresponding to the second dam structure and having a cross section with a second curvature greater than the first curvature.

14. The display apparatus of claim 13, wherein
a height of the first side portion with respect to the support substrate gradually decreases with a first slope corresponding to the first curvature as the first side portion becomes more distant from the display area,
a height of the second side portion with respect to the support substrate decreases with a second slope corresponding to the second curvature and greater than the first slope as the second side portion becomes more distant from the display area, and
a width of the second side portion is smaller than a width of the first side portion.

15. The display apparatus of claim 12, wherein
the display area has a rectangular shape including first and second sides opposing each other and third and fourth sides in contact with the first and second sides and opposing each other,
the first surrounding area is in contact with the first side of the display area, and
the second surrounding area is in contact with the second side, the third side, and the fourth side of the display area.

16. The display apparatus of claim 12, wherein
the display panel further includes:
a circuit array disposed on the support substrate and including a plurality of pixel driving circuits corresponding to the plurality of pixel areas and connected to the plurality of emitting devices;
a via layer covering the circuit array; and
a plurality of signal pads disposed in a pad area adjacent to an edge of the support substrate in the first surrounding area, wherein a driving circuit is connected to the plurality of signal pads, and
the emitting array includes:
a plurality of first electrodes disposed on the via layer and corresponding to the plurality of pixel areas;
a pixel defining layer disposed on the via layer, between the plurality of pixel areas, and covering edges of each of the plurality of first electrodes;
a plurality of emitting layers disposed on the plurality of first electrodes, respectively; and
a second electrode disposed on the pixel defining layer and the plurality of emitting layers and corresponding to the plurality of pixel areas.

17. The display apparatus of claim 16, wherein each of the first dam structure and the second dam structure includes:
a first dam layer defined by a same layer as the via layer; and
a second dam layer disposed on the first dam layer and defined by a same layer as the pixel defining layer, and
the plurality of grooves is defined through at least portions of the second dam layer of the second dam structure.

18. The display apparatus of claim 16, wherein
the emitting array further includes a spacer disposed on the pixel defining layer and between the plurality of pixel areas,
the second electrode covers the spacer,
each of the first dam structure and the second dam structure includes:
a first dam layer defined by a same layer as the via layer;
a second dam layer disposed on the first dam layer and defined by a same layer as the pixel defining layer; and
a third dam layer disposed on the second dam layer and defined by a same layer as the spacer, and
the plurality of grooves is defined through at least portions of the third dam layer of the second dam structure.

19. The display apparatus of claim 16, wherein
the plurality of signal pads include a plurality of first touch pads and a plurality of second touch pads,
the touch sensing unit is disposed on the sealing structure, and
the touch sensing unit includes:
a receiving line connected between one receiving electrode adjacent to one side of an edge of a touch sensing area corresponding to the display area among a plurality of receiving electrodes arranged in parallel in a first direction in the touch sensing area and the second touch pad;
a first touch driving line connected between one touch driving electrode adjacent to another side of the edge of the touch sensing area among a plurality of touch driving electrodes arranged in parallel in a second direction crossing the first direction in the touch sensing area and one of the plurality of first touch pads; and
a second touch driving line connected between one touch driving electrode adjacent to another side of the edge of the touch sensing area among the plurality of touch driving electrodes arranged in parallel in the second direction crossing the first direction in the touch sensing area and another of the plurality of first touch pads.

20. The display apparatus of claim 12, wherein a gradient of a side surface of the first dam structure is less than about 45°.
